(19) United States
(12) Patent Application Publication
(10) Pub. No.: US 2026/0159959 A1
(43) Pub. Date: Jun. 11, 2026

(54) DEPOSITION MASK AND METHOD FOR MANUFACTURING THE SAME

(71) Applicant: Samsung Display Co., LTD., Yongin-si (KR)

(72) Inventors: Sung Woon KIM, Yongin-si (KR); Byeong Hoon CHO, Yongin-si (KR)

(21) Appl. No.: 19/181,730

(22) Filed: Apr. 17, 2025

(30) Foreign Application Priority Data
Aug. 29, 2024 (KR) 10-2024-0116492

(51) Int. Cl. C23C 28/04; C23C 14/04; C23C 14/08; C23C 14/24; C23C 14/58; C23C 16/34; C23C 16/56; H10K 71/16

(52) U.S. Cl. CPC C23C 28/04; C23C 14/042; C23C 14/08; C23C 14/24; C23C 14/5873; C23C 16/345; C23C 16/56; H10K 71/166

(57) ABSTRACT

A method for manufacturing a deposition mask, includes, forming a first coating film on a mask substrate, and a second coating film on the first coating film, etching at least a part of the second coating film to form a mask pattern, a hole pattern, and a first sub-key hole, etching at least a part of the mask substrate to form a mask opening, etching at least a part of the first coating film to form a second sub-key hole and a key hole, and forming a second alignment mark inside the key hole.

This application claims priority to Korean Patent Application No. 10-2024-0116492, filed on Aug. 29, 2024, and all the benefits accruing therefrom under 35 U.S.C. § 119, the content of which in its entirety is herein incorporated by reference.

### BACKGROUND

### 1. Technical Field

The invention generally relates to a deposition mask, and more particularly to a deposition mask and a method for manufacturing the same.

### 2. Description of the Related Art

With the advance of an information-oriented society, more and more demands are placed on display devices for displaying images in various ways. The display device may be a display device such as a liquid crystal display, a field emission display and a light emitting display. The light emitting display may include an organic light emitting display device including an organic light emitting diode as a light emitting element or an inorganic light emitting display device including an inorganic light emitting diode as a light emitting element.

Recently, there is an increasing need for a display device that provides high-resolution images, for example, images with a resolution of 3000 PPI (Pixels Per Inch) or more. To this end, an organic light emitting diode on silicon (OLEDoS), which is a high-resolution small organic light emitting display device, is used. The OLEDoS is an image display device in which an organic light emitting diode (OLED) is disposed on a semiconductor wafer substrate including complementary metal oxide semiconductor (CMOS).

Moreover, in order to manufacture a self-luminous display device such as an organic light emitting display device, a deposition method is mainly used as a technology for depositing an organic material for each pixel, in which a thin film mask is firmly attached to a substrate to deposit the organic material at a required position. When depositing the organic material in a large-area organic light emitting display device, a fine metal mask (FMM), which is a thin-film metal mask, is widely used. However, this metal mask is not suitable for high-resolution patterning.

### SUMMARY

Aspects of the invention provide a deposition mask with an improved recognition rate of an alignment mark and a method for manufacturing the same.

Aspects of the invention also provide a deposition mask with improved quality reliability and a method for manufacturing the same.

However, aspects of the invention are not restricted to those set forth herein. The above and other aspects of the invention will become more apparent to one of ordinary skill in the art to which the invention pertains by referencing the detailed description of the invention given below.

According to an aspect of the invention, there is provided a method for manufacturing a deposition mask, including, forming a first coating film on a mask substrate, and a second coating film on the first coating film, etching at least a part of the second coating film to form a mask pattern, a hole pattern, and a first sub-key hole, etching at least a part of the mask substrate to form a mask opening, etching at least a part of the first coating film to form a second sub-key hole and a key hole, and forming a second alignment mark inside the key hole.

In an embodiment, the mask substrate contains silicon, the first coating film contains silicon oxide, and the second coating film contains silicon nitride.

In an embodiment, the second coating film contains low stress nitride.

In an embodiment, the first coating film is formed by thermal evaporation, and the second coating film is formed by a low-pressure chemical vapor deposition (LPCVD) process.

In an embodiment, the hole pattern and the first sub-key hole are formed by the same process.

In an embodiment, the forming of the second alignment mark is performed after the forming of the first coating film and the second coating film.

In an embodiment, the forming of the second alignment mark is performed after the forming of the mask opening and the forming of the second sub-key hole.

In an embodiment, the forming of the second alignment mark comprises printing a mark material inside the key hole.

In an embodiment, the forming of the second alignment mark comprises removing a mark material layer disposed on the second coating film.

In an embodiment, the removing of the mark material layer includes a chemical mechanical polishing (CMP) process.

In an embodiment, the forming of the second alignment mark includes removing a mark material layer disposed on the photoresist layer together with removal of a photoresist layer.

In an embodiment, the removal of the photoresist layer is performed by a stripping process.

According to an aspect of the invention, there is provided a deposition mask including, a mask substrate composed of a semiconductor wafer, a first coating film disposed on the mask substrate, a second coating film disposed on the first coating film, and including a hole pattern and a mask pattern alternately disposed, a key hole penetrating the first coating film and the second coating film, and an alignment mark disposed inside the key hole.

In an embodiment, the key hole includes a first sub-key hole penetrating the first coating film and a second sub-key hole penetrating the second coating film.

In an embodiment, the deposition mask may further include a mask opening penetrating the mask substrate and the first coating film, wherein the mask opening overlaps the mask pattern and the hole pattern.

In an embodiment, the mask opening does not overlap the key hole.

In an embodiment, the key hole and the mask opening communicate with each other to form a through hole.

In an embodiment, a top surface of the alignment mark is exposed.

In an embodiment, the top surface of the alignment mark is not in contact with the first coating film and the second coating film.

In an embodiment, a side surface of the alignment mark is in direct contact with a side surface of the key hole.

In accordance with the deposition mask and the method for manufacturing the same, according to an embodiment, it is possible to improve the recognition rate of the alignment mark.

In accordance with the deposition mask and the method for manufacturing the same, according to an embodiment, it is possible to improve the quality reliability.

However, effects according to embodiments are not limited to those exemplified above and various other effects are incorporated herein.

### BRIEF DESCRIPTION OF THE DRAWINGS

The above and other aspects and features of the invention will become more apparent by describing in detail embodiments thereof with reference to the attached drawings, in which:

FIG. 1 is an exploded perspective view showing a display device, according to an embodiment;

FIG. 2 is a block diagram illustrating a display device, according to an embodiment;

FIG. 3 is an equivalent circuit diagram of a first sub-pixel, according to an embodiment;

FIG. 4 is a layout diagram illustrating an example of a display panel, according to an embodiment;

FIG. 5 is a layout diagram showing an example of the display area of FIG. 4, according to an embodiment;

FIG. 6 is a layout diagram showing another example of the display area of FIG. 4, according to an embodiment;

FIG. 7 is a cross-sectional view illustrating an example of a display panel taken along line X1-X1′ of FIG. 5, according to an embodiment;

FIG. 8 is a cross-sectional view illustrating still another example of a display panel taken along line X1-X1′ of FIG. 5, according to an embodiment;

FIG. 9 is a cross-sectional view illustrating still another example of a display panel taken along line X1-X1′ of FIG. 5, according to an embodiment;

FIG. 10 is a perspective view illustrating a head mounted display, according to an embodiment;

FIG. 11 is an exploded perspective view illustrating an example of the head mounted display of FIG. 9, according to an embodiment;

FIG. 12 is a perspective view illustrating a head mounted display, according to an embodiment;

FIG. 13 is a plan view showing a mother semiconductor substrate including a display cell, according to an embodiment;

FIG. 14 is a plan view showing a deposition mask, according to an embodiment;

FIG. 15 is a cross-sectional view showing an example of a cross section taken along line X2-X2′ of FIG. 14, according to an embodiment;

FIG. 16 is a cross-sectional view showing another example of a cross section taken along line X2-X2′ of FIG. 14, according to an embodiment;

FIG. 17 is a perspective view showing a process of manufacturing a display device using a deposition mask, according to an embodiment;

FIG. 18 is a cross-sectional view showing a process of manufacturing a display device using a deposition mask, according to an embodiment;

FIG. 19 is a flowchart showing a method for manufacturing a deposition mask, according to, according to an embodiment;

FIG. 20 is a cross-sectional view showing step S100 of FIG. 19, according to an embodiment;

FIG. 21 is a cross-sectional view showing step S200 of FIG. 19, according to an embodiment;

FIG. 22 is a cross-sectional view showing step S300 of FIG. 19, according to an embodiment;

FIG. 23 is a cross-sectional view showing step S400 of FIG. 19, according to an embodiment;

FIG. 24 is a cross-sectional view showing step S500 of FIG. 19, according to an embodiment;

FIG. 25 is a flowchart illustrating a step of forming a second alignment mark, according to an embodiment;

FIG. 26 is a cross-sectional view showing step S510_1 of FIG. 25, according to an embodiment;

FIG. 27 is a flowchart illustrating a step of forming a second alignment mark, according to another embodiment;

FIG. 28 is a cross-sectional view showing step S510_2 of FIG. 27, according to an embodiment;

FIG. 29 is a cross-sectional view showing step S520_2 of FIG. 27, according to an embodiment;

FIG. 30 is a cross-sectional view showing step S520_2 of FIG. 27, according to an embodiment;

FIG. 31 is a flowchart illustrating a step of forming a second alignment mark, according to still another embodiment;

FIG. 32 is a cross-sectional view showing step S510_3 of FIG. 31, according to an embodiment;

FIG. 33 is a cross-sectional view showing step S520_3 of FIG. 31, according to an embodiment;

FIG. 34 is a cross-sectional view showing step S530_3 of FIG. 31, according to an embodiment; and

FIG. 35 is a cross-sectional view showing step S540_3 of FIG. 31, according to an embodiment.

### DETAILED DESCRIPTION

The invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments will be described in detail with reference to the accompanying drawings.

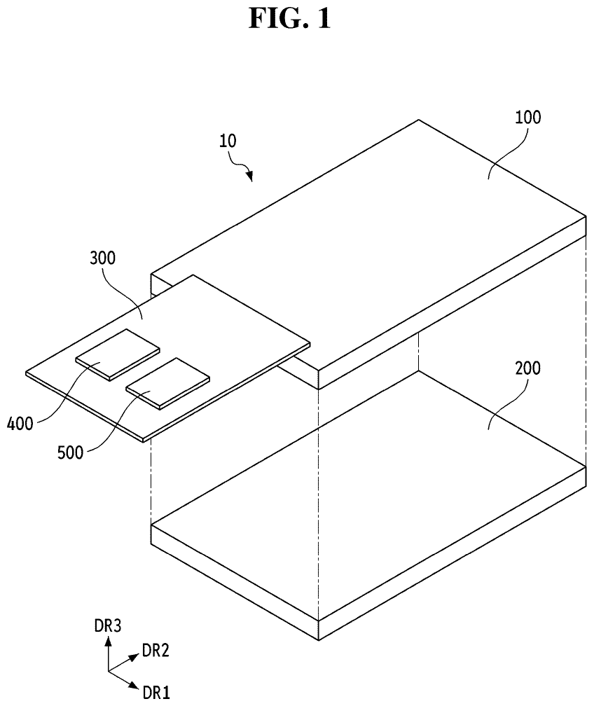

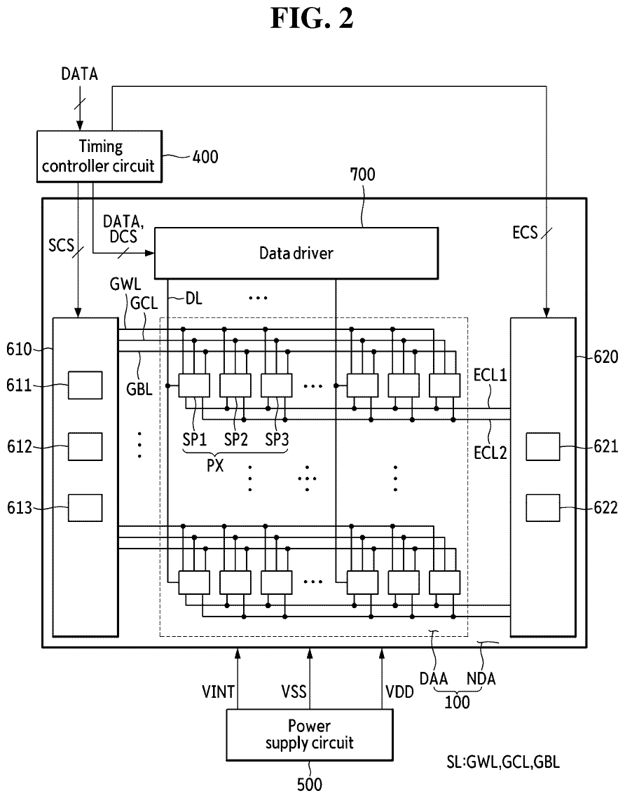

FIG. 1 is an exploded perspective view showing a display device, according to an embodiment. FIG. 2 is a block diagram illustrating a display device, according to an embodiment.

In an embodiment and referring to FIGS. 1 and 2, a display device 10 is a device displaying a moving image or a still image. The display device 10, according to an embodiment, may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10, according to an embodiment, may be applied as a display unit of a television, a laptop, a monitor, a billboard, or an Internet-of-Things (IoT) terminal. In another embodiment, the display device 10 may be applied to a smart watch, a watch phone, a head mounted display (HMD) for implementing virtual reality and augmented reality, and the like.

The display device 10, according to an embodiment, includes a display panel 100, a heat dissipation layer 200, a circuit board 300, a timing control circuit 400, and a power supply circuit 500.

In an embodiment, the display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the invention is not limited thereto.

In an embodiment, the display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

In an embodiment, the plurality of pixels PX may be disposed in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

In an embodiment, the plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

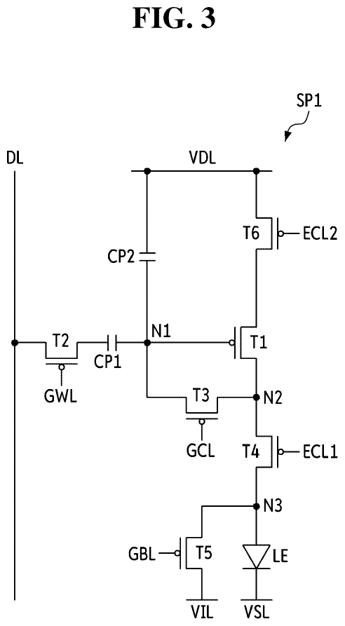

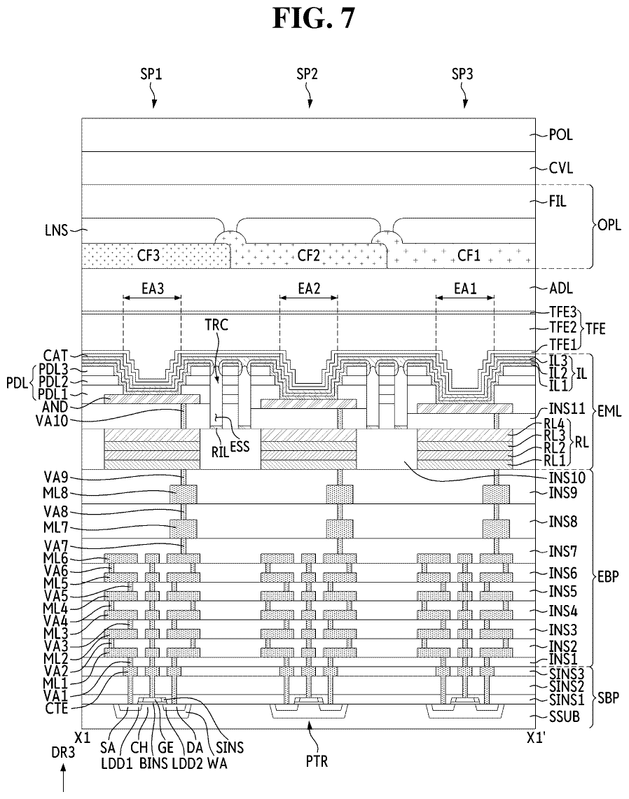

In an embodiment, the plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on a semiconductor substrate SSUB (see FIG. 7). For example, the plurality of pixel transistors of the data driver 700 may be formed of complementary metal oxide semiconductor (CMOS), but the invention is not limited thereto.

In an embodiment, each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL and emit light from the light emitting element according to the data voltage.

In an embodiment, the scan driver 610, the emission driver 620, and the data driver 700 may be disposed in the non-display area NDA.

In an embodiment, the scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS, but the invention is not limited thereto.

In an embodiment, the scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

In an embodiment, the emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

In an embodiment, the data driver 700 may include a plurality of data transistors, and the plurality of data transistors may be formed on the semiconductor substrate SSUB (see FIG. 7) through a semiconductor process. For example, the plurality of data transistors may be formed of CMOS, but the invention is not limited thereto.

In an embodiment, the data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

In an embodiment, the heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

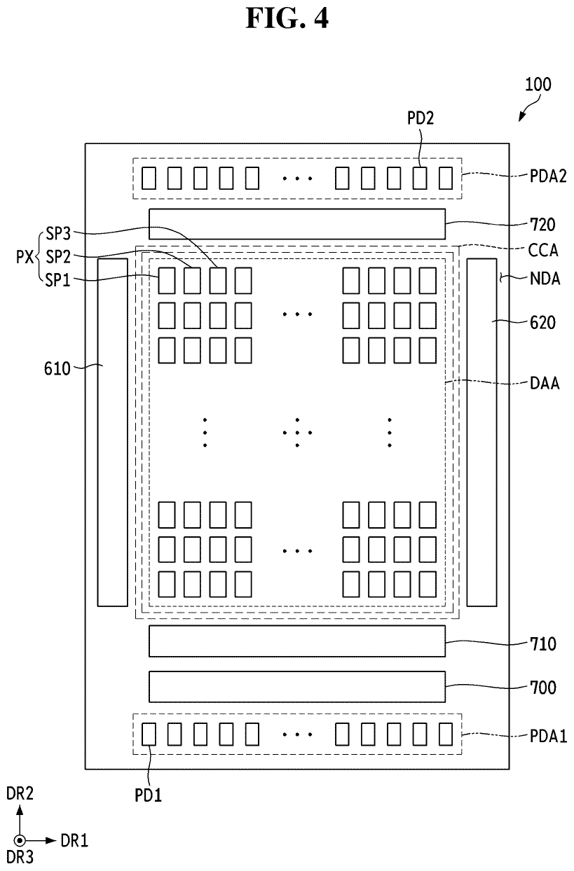

In an embodiment, the circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

In an embodiment, the power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

In an embodiment, each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS, but the present disclosure is not limited thereto. Each of the timing control circuit 400 and the power supply circuit 500 may be disposed between the data driver 700 and the first pad portion PDA1 (see FIG. 4).

FIG. 3 is an equivalent circuit diagram of a first sub-pixel, according to an embodiment.

In an embodiment and referring to FIG. 3, a first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

In an embodiment, the first sub-pixel SP1 includes a plurality of transistors T1 to T6, a light emitting element LE, a first capacitor CP1, and a second capacitor CP2.

In an embodiment, the light emitting element LE emits light in response to a driving current flowing through the channel of a first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

In an embodiment, the first transistor T1 may be a driving transistor that controls a source-drain current (hereinafter referred to as “driving current”) flowing between the source electrode and the drain electrode thereof according to a voltage applied to the gate electrode thereof.

In an embodiment, a second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

In an embodiment, a third transistor T3 may be disposed between a first node N1 and a second node N2. The third transistor T3 is turned on by the write control signal of the write control line GCL to connect the first node N1 to the second node N2. For this reason, when the gate electrode and the source electrode of the first transistor T1 are connected, the first transistor T1 may operate like a diode.

In an embodiment, a fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

In an embodiment, a sixth transistor T6 may be disposed between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

In an embodiment, the first capacitor CP1 is formed between the first node N1 and the drain electrode of the second transistor T2. The second capacitor CP2 is formed between the gate electrode of the first transistor T1 and the second driving voltage line VDL.

In an embodiment, each of the transistors T1 to T6 may be a metal-oxide-semiconductor field effect transistor (MOSFET). For example, each of the transistors T1 to T6 may be a P-type MOSFET, but the invention is not limited thereto. Each of the transistors T1 to T6 may be an N-type MOSFET. Alternatively, some of the transistors T1 to T6 may be P-type MOSFETs, and each of the remaining transistors may be an N-type MOSFET.

In an embodiment, although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, in an embodiment, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel, according to an embodiment.

In an embodiment and referring to FIG. 4, the display area DAA of the display panel 100 includes the plurality of pixels PX arranged in a matrix form. The non-display area NDA of the display panel 100, according to an embodiment, includes the scan driver 610, the emission driver 620, the data driver 700, a first distribution circuit 710, a second distribution circuit 720, the first pad portion PDA1, and a second pad portion PDA2.

In an embodiment, the scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. However, the invention is not limited thereto, and the scan driver 610 and the emission driver 620 may be disposed on both the first side and the second side of the display area DAA.

In an embodiment, the first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2.

In an embodiment, the second pad portion PDA2 may include a plurality of second pads PD2 corresponding to inspection pads that test whether the display panel 100 operates normally. The plurality of second pads PD2 may be connected to a jig or a probe pin during an inspection process or may be connected to a circuit board for inspection. The circuit board for inspection may be a printed circuit board made of a rigid material or a flexible printed circuit board made of a flexible material.

In an embodiment, the second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2.

In an embodiment, the first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

In an embodiment, the second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2.

In an embodiment, a cathode connection part CCA may be an area where a second electrode CAT (see FIG. 7) of a display element layer EML (see FIG. 7) is connected to the first driving voltage line VSL of the non-display area NDA. The cathode connection part CCA may be disposed outside at least one side of the display area DAA. For example, the cathode connection part CCA may be disposed outside at least one side of the display area DAA among the left side, right side, upper side, and lower side of the display area DAA. In another embodiment, the cathode connection part CCA may be disposed to surround the display area DAA as shown in FIG. 4 in order to minimize deviations of the first driving voltage VSS caused by voltage drop (IR drop) or voltage rise (IR rising) of the second electrode CAT in the display area DAA.

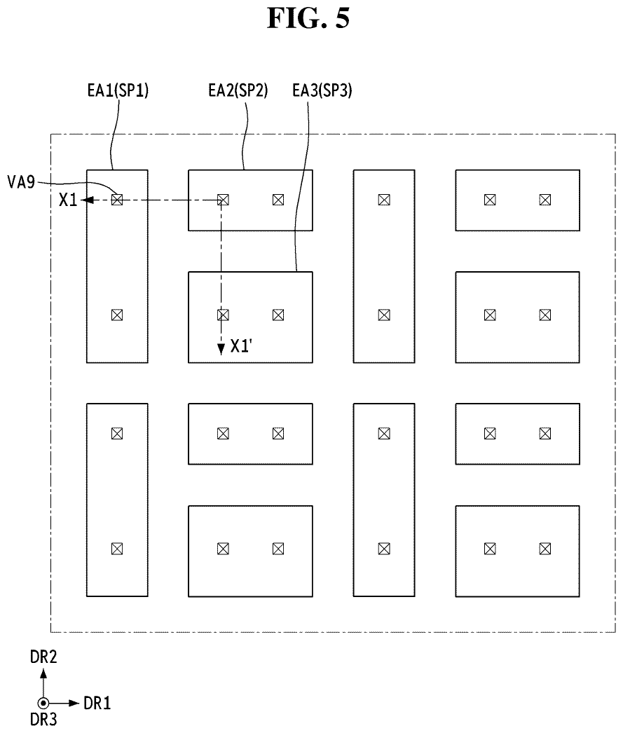

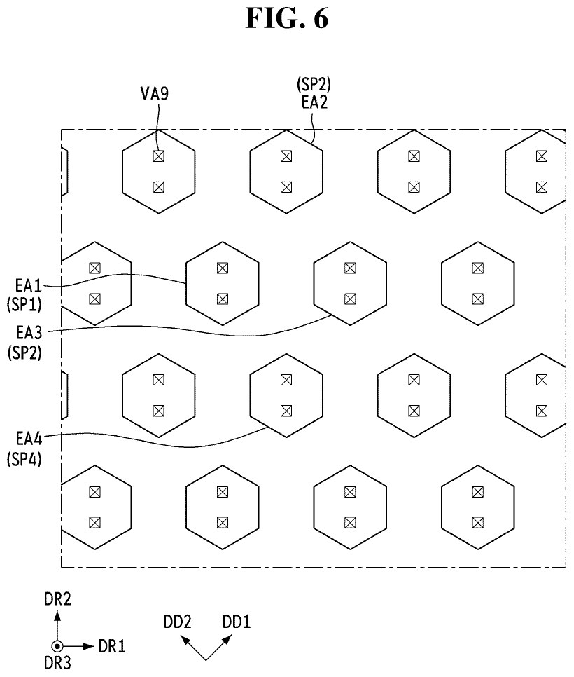

FIG. 5 is a layout diagram showing an example of the display area of FIG. 4, according to an embodiment. FIG. 6 is a layout diagram showing another example of the display area of FIG. 4, according to an embodiment.

In an embodiment and referring to FIGS. 5 and 6, each of the pixels PX includes a first emission area EA1 that is an emission area of the first sub-pixel SP1, a second emission area EA2 that is an emission area of the second sub-pixel SP2, and a third emission area EA3 that is an emission area of the third sub-pixel SP3.

In an embodiment, the first emission area EA1, the second emission area EA2, and the third emission area EA3 may have, in a plan view, a quadrilateral or hexagonal shape as shown in FIGS. 5 and 6, but the invention is not limited thereto. The first emission area EA1, the second emission area EA2, and the third emission area EA3 may have a polygonal shape other than a quadrangle or hexagon, a circular shape, an elliptical shape, or an atypical shape in a plan view.

In an embodiment and as shown in FIG. 5, in each of the plurality of pixels PX, the first emission area EA1 and the second emission area EA2 may be disposed adjacent to each other in the first direction DR1. Further, the first emission area EA1 and the third emission area EA3 may be disposed adjacent to each other in the first direction DR1. In addition, the second emission area EA2 and the third emission area EA3 may be disposed adjacent to each other in the second direction DR2. The area of the first emission area EA1, the area of the second emission area EA2, and the area of the third emission area EA3 may be different.

In another embodiment, as shown in FIG. 6, the emission areas EA1, EA2, EA3, and EA4 may have a hexagonal shape in a plan view. In this case, the first emission area EA1 and the third emission area EA3 may be disposed adjacent in the first direction DR1, and the second emission area EA2 and the fourth emission area EA4 may be disposed adjacent in the second direction DR2. Additionally, the first emission area EA1 and the second emission area EA2 may be disposed adjacent in a first diagonal direction DD1, and the second emission area EA2 and the third emission area EA3 may be disposed adjacent in a second diagonal direction DD2. Additionally, the first emission area EA1 and the fourth emission area EA4 may be disposed adjacent in the second diagonal direction DD2, and the third emission area EA3 and the fourth emission area EA4 may be disposed adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction the is directed perpendicular to the first diagonal direction DD1.

In an embodiment, the first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to about 460 nm, the green wavelength band may be a wavelength band of light whose main peak wavelength is in the range of approximately 480 nm to about 560 nm, and the red wavelength band may be a wavelength band of light whose main peak wavelength is in the range of approximately 600 nm to about 750 nm.

In an embodiment, each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the invention is not limited thereto.

In an embodiment, the emission areas of the plurality of pixels PX may be disposed in a stripe structure where the emission areas are arranged in the first direction DR1, in a PenTile® structure where the emission areas EA1, EA2, EA3, and EA4 are arranged in a rhombus shape as shown in FIG. 6, or in a hexagonal structure where the emission areas are arranged in a hexagonal shape.

FIG. 7 is a cross-sectional view illustrating an example of a display panel taken along line X1-X1′ of FIG. 5, according to an embodiment.

In an embodiment and referring to FIG. 7, the display panel 100 includes a semiconductor backplane SBP, a light emitting element backplane EBP, the display element layer EML, an encapsulation layer TFE, an optical layer OPL, a cover layer CVL, and a polarizing plate POL.

In an embodiment, the semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the transistors T1 to T6 described with reference to FIG. 3.

In an embodiment, the semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. In an embodiment, when the first type impurity is an n-type impurity, the second type impurity may be a p-type impurity.

In an embodiment, each of the plurality of well regions WA includes a source region SA corresponding to the source electrode of the pixel transistor PTR, a drain region DA corresponding to the drain electrode thereof, and a channel region CH disposed between the source region SA and the drain region DA.

In an embodiment, a lower insulating film BINS may be disposed between a gate electrode GE and the well region WA. A side insulating film SINS may be disposed on the side surface of the gate electrode GE. The side insulating film SINS may be disposed on the lower insulating film BINS.

In an embodiment, each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

In an embodiment, each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

In an embodiment, a first semiconductor insulating film SINS1 may be disposed on the semiconductor substrate SSUB. A second semiconductor insulating film SINS2 may be disposed on the first semiconductor insulating film SINS1.

In an embodiment, the plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through a hole penetrating the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, a third semiconductor insulating film SINS3 may be disposed on a side surface of each of the plurality of contact terminals CTE. The top surface of each of the plurality of contact terminals CTE may be exposed without being covered by the third semiconductor insulating film SINS3.

In an embodiment, each of the first semiconductor insulating film SINS1, the second semiconductor insulating film SINS2, and the third semiconductor insulating film SINS3 may be formed of silicon carbonitride (SiCN) or a silicon oxide (SiOx)-based inorganic film, but the invention is not limited thereto.

In an embodiment, the semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

In an embodiment, the light emitting element backplane EBP includes a plurality of conductive layers ML1 to ML8, a plurality of vias VA1 to VA9, and a plurality of insulating films INS1 to INS11. In addition, the light emitting element backplane EBP includes a plurality of insulating films INS1 to INS9.

In an embodiment, the insulating films INS1 to INS8 serve to insulate the conductive layers ML1 to ML8. The conductive layers ML1 to ML8 serve to connect the plurality of contact terminals CTE exposed from the semiconductor backplane SBP to thereby implement the circuit of the first sub-pixel SP1 shown in FIG. 3.

For example, in an embodiment, the transistors T1 to T6 are merely formed in the semiconductor backplane SBP, and the connection of the transistors T1 to T6 and the capacitors C1 and C2 is accomplished through the conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the conductive layers ML1 to ML8.

In an embodiment, the conductive layers ML1 to ML8 and the vias VA1 to VA8 may be formed of substantially the same material. The conductive layers ML1 to ML8 and the vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The vias VA1 to VA8 may be made of substantially the same material. The insulating films INS1 to INS8 may be formed of a silicon oxide (SiOx)-based inorganic film, but the invention is not limited thereto.

In an embodiment, a ninth insulating film INS9 may be disposed on the eighth insulating film INS8 and the eighth conductive layer ML8. The ninth insulating film INS9 may be formed of a silicon oxide (SiOx)-based inorganic film, but the invention is not limited thereto.

In an embodiment, each of the ninth vias VA9 may penetrate the ninth insulating film INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

In an embodiment, the display element layer EML may be disposed on the light emitting element backplane EBP. The display element layer EML may include insulating films INS10 and INS11, a reflective electrode RL, the first electrodes AND, a light emitting stack IL, the second electrode CAT, a pixel defining film PDL, and a plurality of trenches TRC.

In an embodiment, the reflective electrode RL may be disposed on the ninth insulating film INS9. The reflective electrode RL may include at least one reflective electrode RL1, RL2, RL3, and RL4. For example, the reflective electrode RL may include the reflective electrodes RL1, RL2, RL3, and RL4 as shown in FIG. 7.

In an embodiment, the first reflective electrodes RL1 may be disposed on the ninth interlayer insulating layer INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

In an embodiment, since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

In an embodiment, the first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

In an embodiment, the tenth interlayer insulating layer INS10 may be disposed on the ninth interlayer insulating layer INS9. The tenth interlayer insulating film INS10 may be disposed between the reflective electrodes RL that are disposed adjacent to each other. The tenth interlayer insulating film INS10 may be a film for flattening a stepped portion caused by the reflective electrodes RL. The eleventh interlayer insulating layer INS11 may be disposed on the tenth interlayer insulating layer INS10 and the reflective electrode layer RL.

In an embodiment, the tenth interlayer insulating film INS10 and the eleventh interlayer insulating film INS11 may be formed of a silicon oxide (SiOx)-based inorganic film, but the invention is not limited thereto.

In an embodiment, the eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode layer RL to the second electrode CAT according to a main wavelength of light emitted from each of the first sub-pixel SP1, the second sub-pixel SP2, and the third sub-pixel SP3, the thickness of the eleventh interlayer insulating layer INS11 may be set for each of the first sub-pixel SP1, the second sub-pixel SP2, and the third sub-pixel SP3.

For example, in an embodiment and as shown in FIG. 7, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

In an embodiment, each of the tenth vias VA10 may penetrate the eleventh interlayer insulating layer INS11 and be connected to the exposed ninth metal layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

In an embodiment, the first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the vias VA1 to VA9, the metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

In an embodiment, the pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

In an embodiment, the first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

In an embodiment, the pixel defining film PDL may include pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film. In an embodiment, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In an embodiment, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

In an embodiment, each of the plurality of trenches TRC may penetrate the first pixel defining film PDL1, the second pixel defining film PDL2, and the third pixel defining film PDL3. The eleventh interlayer insulating layer INS11 may be partially recessed at each of the plurality of trenches TRC.

In an embodiment, at least one trench TRC may be disposed between the neighboring sub-pixels SP1, SP2, and SP3. Although FIG. 7 illustrates that two trenches TRC are disposed between the neighboring sub-pixels SP1, SP2, and SP3, the invention is not limited thereto.

In an embodiment, the light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but the invention is not limited thereto. For example, the light emitting stack IL may have a two-tandem structure including two stack layers as shown in FIG. 7.

In an embodiment, in the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

In an embodiment, the first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

In an embodiment, a first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

In an embodiment, a second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

In an embodiment, the first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film IL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In an embodiment, in the three-tandem structure, each of the plurality of trenches TRC may be a structure for cutting off the hole transport layers, the first charge generation layer, and the second charge generation layer of the stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In an embodiment, in order to stably cut off the stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML disposed between the neighboring sub-pixels SP1, SP2, and SP3, a different structure may be present instead of the trench TRC. For example, instead of the trench TRC, a reverse-tapered partition wall may be disposed on the pixel defining film PDL.

In addition, FIG. 7 illustrates an embodiment where the light emitting stack IL that emits light is disposed in the first emission area EA1, the second emission area EA2, and the third emission area EA3, but the invention is not limited thereto. For example, instead of the light emitting stack IL, the first light emitting layer may be disposed in the first emission area EA1 and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, color filters CF1, CF2, and CF3 of the optical layer OPL may be omitted.

In an embodiment, the second electrode CAT may be disposed on the light emitting stack IL and may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the sub-pixels SP1, SP2, and SP3 due to a micro-cavity effect.

In an embodiment, the encapsulation layer TFE may be disposed on the display element layer EML and may include at least one inorganic film TFE1 and TFE2 to reduce or prevent oxygen or moisture from permeating into the display element layer EML. The first encapsulation inorganic film TFE1 may be disposed on the second electrode CAT, and the second encapsulation inorganic film TFE2 may be disposed on the first encapsulation inorganic film TFE1. The first encapsulation inorganic film TFE1 and the second encapsulation inorganic film TFE3 may be formed of multiple layers in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In addition, in an embodiment, the encapsulation layer TFE may include at least one organic film to protect the display element layer EML from foreign substances such as dust. The at least one organic film of the encapsulation layer TFE may be disposed between the first encapsulation inorganic film TFE1 and the second encapsulation inorganic film TFE2. The at least one organic film of the encapsulation layer TFE may be a monomer. In another embodiment, at least one organic film of the encapsulating layer TFE may be an organic film such as acryl resin, epoxy resin, phenolic resin, polyamide resin, polyimide resin or the like.

In an embodiment, an adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

In an embodiment, the optical layer OPL includes a plurality of color filters CF1, CF2, and CF3, a plurality of lenses LNS, and a filling layer FIL. The plurality of color filters CF1, CF2, and CF3 may include the color filters CF1, CF2, and CF3. The color filters CF1, CF2, and CF3 may be disposed on the adhesive layer ADL.

In an embodiment, the first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

In an embodiment, the second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

In an embodiment, the third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

In an embodiment, the plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex shaped in an upward direction.

In an embodiment, the filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

In an embodiment, the cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

In an embodiment, the polarizing plate may be disposed on one surface of the cover layer CVL. The polarizing plate may be a structure for reducing or preventing visibility degradation caused by reflection of external light. The polarizing plate may include a linear polarizing plate and a phase retardation film. For example, the phase retardation film may be a λ/4 plate (quarter-wave plate), but the invention is not limited thereto. However, when visibility degradation caused by reflection of external light is sufficiently overcome by the color filters CF1, CF2, and CF3, the polarizing plate may be omitted.

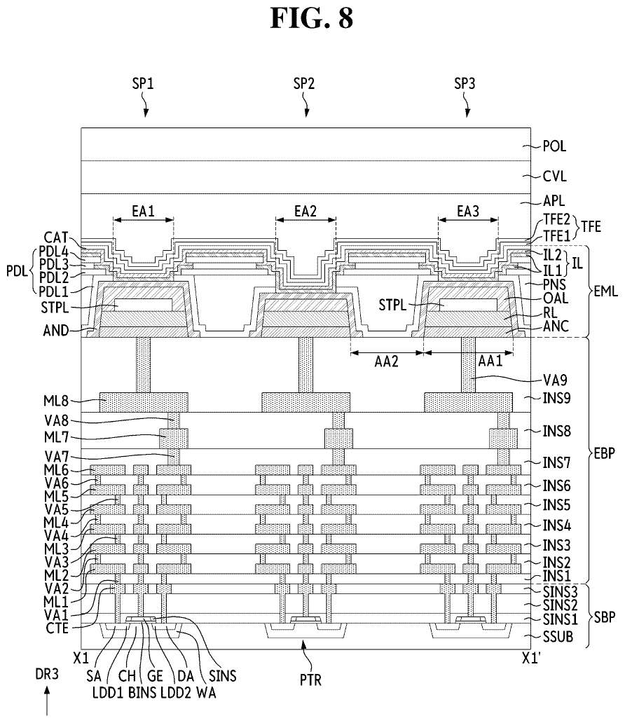

FIG. 8 is a cross-sectional view illustrating still another example of a display panel taken along line X1-X1′ of FIG. 5, according to an embodiment.

The embodiment of FIG. 8 differs from the embodiment of FIG. 7 in that the first electrode AND of each of the light emitting elements LE is in contact with and electrically connected to the side surface of a connection electrode ANC connected to the eighth conductive layer ML8. The embodiment of FIG. 8 also differs from the embodiment of FIG. 7 in that the trench TRC is omitted, and instead, the third pixel defining film PDL3 and a fourth pixel defining film PDL4 have an eave-shaped or mushroom-shaped cross-sectional structure. In the embodiment of FIG. 8, redundant description of parts already described in the embodiment of FIG. 7 will be omitted.

In an embodiment and referring to FIG. 8, the plurality of connection electrodes ANC may be respectively disposed on first portions AA1 of the ninth insulating film INS9. Each of the plurality of connection electrodes ANC may be disposed on the first portion AA1 of the ninth insulating film INS9 corresponding thereto. A plurality of connection electrodes ANC may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the invention is limited thereto.

In an embodiment, a plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, each of the plurality of reflective electrodes RL may include aluminum (Al) having high reflectivity.

In an embodiment, a plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may be formed of a silicon oxide (SiOx)-based inorganic film, but the invention is not limited thereto.

In an embodiment, in each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thickness of the optical auxiliary film OAL in the first emission area EA1, the second emission area EA2, and the third emission area EA3 may be substantially the same.

In an embodiment, due to the step layer STPL, the distance between the reflective electrode RL and the first electrode AND in the first emission area EA1 and the third emission area EA3 may be larger than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light emitting stack IL, and the wavelength and resonance distance of light emitted from the second stack layer IL2.

In an embodiment, each of the light emitting elements LE may include the first electrode AND, a light emitting stack IL, and a second electrode CAT.

In an embodiment, the first electrode AND of each of the light emitting elements LE may be disposed on the optical auxiliary film OAL corresponding thereto. Since the connection electrode ANC, the reflective electrode RL, and the optical auxiliary film OAL are sequentially stacked, the first electrode AND of each of the light emitting elements LE may be disposed on the top and side surfaces of the optical auxiliary film OAL, the side surface of the reflective electrode RL, and the side surface of the connection electrode ANC. As a result, the first electrode AND of each of the light emitting elements LE may be in contact with the side surface of the reflective electrode RL and the side surface of the connection electrode ANC and be electrically connected thereto. Therefore, compared to when the first electrode AND of each of the light emitting elements LE is connected to the reflective electrode RL exposed through a through hole penetrating the optical auxiliary film OAL, the number of mask processes may be reduced, thereby lowering manufacturing cost and increasing manufacturing efficiency.

In an embodiment, the first electrode AND of each of the light emitting elements LE may be connected to the drain region DA or the source region SA of the pixel transistor PTR through the connection electrode ANC, the vias VA1 to VA9, the conductive layers ML1 to ML8, and the contact terminal CTE.

In an embodiment, the ninth insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth insulating film INS9 may be substantially the same.

In another embodiment, the thickness of the first portion AA1 of the ninth insulating film INS9 may be greater than the thickness of the second portion AA2. In this case, the side surface of the first portion AA1 of the ninth insulating film INS9 may be exposed, and the first electrode AND of each of the light emitting elements LE may be disposed on the exposed side surface of the first portion AA1 of the ninth insulating film INS9.

In an embodiment, the first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), an alloy including any one of them, or a transparent conductive oxide. For example, the first electrode AND of each of the light emitting elements LE may include titanium (Ti), titanium nitride (TiN), indium tin oxide (ITO), or indium zinc oxide (IZO), but the invention is limited thereto.

In an embodiment, the pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

In an embodiment, the pixel defining film PDL may include pixel defining films PDL1, PDL2, PDL3, and PDL4.

In an embodiment, the first pixel defining film PDL1 may be disposed on the first electrode AND of each of the light emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth insulating film INS9.

In an embodiment, a planarization film PNS is a film for planarizing the stepped portion caused by the connection electrode ANC, the reflective electrode RL, and the optical auxiliary film OAL.

In an embodiment, the planarization film PNS may be disposed on the first pixel defining film PDL1 that covers the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth insulating film INS9.

In an embodiment, the planarization film PNS may be disposed between the connection electrodes ANC that are disposed adjacent in the first direction DR1 or the second direction DR2. The planarization film PNS may be disposed between the reflective electrodes RL that are disposed adjacent in the first direction DR1 or the second direction DR2. The planarization film PNS may be disposed between the optical auxiliary films OAL that are disposed adjacent in the first direction DR1 or the second direction DR2.

In an embodiment, the step layer STPL is not present in the second emission area EA2, whereas the step layer STPL is present in each of the first emission area EA1 and the third emission area EA3. As a result, the height of the connection electrode ANC, the reflective electrode RL, and the optical auxiliary film OAL in the second emission area EA2 may be smaller than the height of the connection electrode ANC, the reflective electrode RL, the step layer STPL, and the optical auxiliary film OAL in each of the first emission area EA1 and the third emission area EA3. Therefore, the planarization film PNS may cover the top surface of the first pixel defining film PDL1 disposed on the top surface of the first electrode AND disposed in the second emission area EA2.

In contrast, in an embodiment, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

In an embodiment, the second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may be formed of a silicon nitride (SiNx)-based inorganic film, whereas the second pixel defining film PDL2, the fourth pixel defining film PDL4, and the planarization film PNS may be formed of a silicon oxide (SiOx)-based inorganic film. The first pixel defining film PDL1 is formed of a material different from that of the planarization film PNS, and thus may serve as a stopper in a chemical mechanical polishing process for the planarization film PNS.

In an embodiment, when the planarization film PNS and the second pixel defining film PDL2 are both formed as a silicon oxide (SiOx)-based inorganic film, the planarization film PNS and the second pixel defining film PDL2 may be formed as a single film.

In an embodiment, since the length of the third pixel defining film PDL3 in one direction is smaller than the length of the fourth pixel defining film PDL4 in the one direction, the bottom surface of the fourth pixel defining film PDL4 may be exposed without being covered by the third pixel defining film PDL3. In other words, the third pixel defining film PDL3 and the fourth pixel defining film PDL4 may have an eave-shaped or mushroom-shaped cross-sectional structure.

In an embodiment, the light emitting stack IL may be disposed on the first electrode AND and the pixel defining film PDL. The light emitting stack IL may include the first stack layer IL1 and the second stack layer IL2 that emit different lights. When the light emitting stack IL has a two-tandem structure, one of the first stack layer IL1 and the second stack layer IL2 may emit light that includes the wavelength range of any one of the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

In an embodiment, a charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

In an embodiment, since the first stack layer IL1 cannot be formed on the bottom surface of the fourth pixel defining film PDL4 that is exposed without being covered by the third pixel defining film PDL3, it may be cut off due to the eave-shaped or mushroom-shaped cross-sectional structure of the third pixel defining film PDL3 and the fourth pixel defining film PDL4. In this case, the first hole transport layer of the first stack layer IL1, and a charge generation layer disposed between the first stack layer IL1 and the second stack layer IL2 may also be cut off. Additionally, although FIG. 8 illustrates that the second stack layer IL2 is connected without being cut off, the second hole transport layer of the second stack layer IL2 may be cut off, and the second electron transport layer of the second stack layer IL2 may be connected without being cut off. Therefore, a leakage current may be prevented from flowing through the first hole transport layer of the first stack layer IL1, the second hole transport layer of the second stack layer IL2, and the charge generation layer CGL, between the adjacent emission areas EA1, EA2, and EA3. Accordingly, it is possible to prevent the light emitting stack IL in the adjacent emission areas EA1, EA2, and EA3 from emitting light other than the originally intended light due to the influence of the above current.

FIG. 8 illustrates an embodiment where a two-tandem structure in which the light emitting stack IL includes two stack layers IL1 and IL2, but the invention is not limited thereto. For example, the light emitting stack IL may have a three-tandem structure including three stack layers as shown in FIG. 7. In this case, the height of the third pixel defining film PDL3 may be adjusted to design the charge generation layer between the first stack layer IL1 and the second stack layer IL2, and the charge generation layer between the second stack layer IL2 and the third stack layer IL3 to be cut off. In another embodiment, as shown in FIG. 7, the trench TRC penetrating the first pixel defining film PDL1, the eleventh interlayer insulating film INS11 the second pixel defining film PDL2, and the third pixel defining film PDL3 may be added. In this case, the trench TRC may penetrate at least a part of the ninth insulating film INS9, but the invention is not limited thereto.

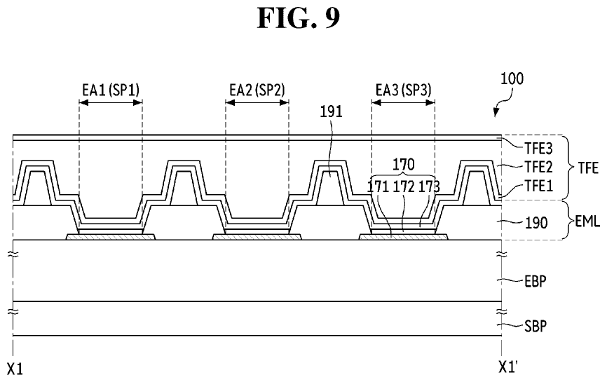

FIG. 9 is a cross-sectional view illustrating still another example of a display panel taken along line X1-X1′ of FIG. 5, according to an embodiment.

Referring to FIG. 9 in addition to FIGS. 7 and 8, in some embodiments, the display device 10 may include the display panel 100 according to the embodiment of FIG. 9.

The display panel 100, according to the embodiment of FIG. 9, may include the semiconductor backplane SBP, the light emitting element backplane EBP, the display element layer EML, and the encapsulation layer TFE. However, the invention is not limited thereto, and it may further include, like the display panel 100 described with reference to FIGS. 7 and 8, at least one of the optical layer OPL, the cover layer CVL, or the polarizing plate POL on the encapsulation layer TFE.

Descriptions of the semiconductor backplane SBP and the light emitting element backplane EBP are omitted here because they are the same as those of the display panel 100 described with reference to FIG. 7.

In an embodiment, the display element layer EML may be disposed on the light emitting element backplane EBP and may include light emitting elements 170 and a bank 190. Each of the light emitting elements 170 may include a first light emitting electrode 171, a light emitting layer 172, and a second light emitting electrode 173.

In an embodiment, the first light emitting electrode 171 may be disposed on the light emitting element backplane EBP. For example, although not shown in the drawing, the first light emitting electrode 171 may be connected to the eighth conductive layer ML8 through the ninth via VA9 that penetrates the ninth insulating film INS9 and exposes the eighth conductive layer ML8.

In an embodiment, in a top emission structure in which light is emitted toward the second light emitting electrode 173 when viewed with respect to the light emitting layer 172, the first light emitting electrode 171 may be formed of a metal material having high reflectivity to have a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO. The APC alloy is an alloy of silver (Ag), palladium (Pd) and copper (Cu).

In an embodiment, the bank 190 may be disposed to separate the first light emitting electrodes 171 to define the emission areas EA1, EA2, and EA3. The bank 190 may be disposed to cover a part of the edge of the first light emitting electrode 171. The bank 190 may be formed of an organic film such as acryl resin, epoxy resin, phenolic resin, polyamide resin, polyimide resin and the like.

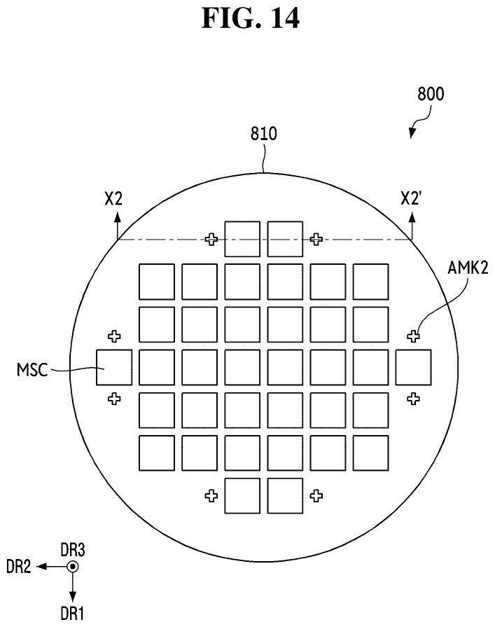

In an embodiment, t spacer 191 may be disposed on the bank 190. The spacer 191 may function to support a deposition mask 800 (see FIG. 14) during the process of manufacturing the light emitting layer 172. The spacer 191 may be formed of an organic film such as acryl resin, epoxy resin, phenolic resin, polyamide resin, polyimide resin and the like.

In an embodiment, each of the emission areas EA1, EA2, and EA3 represents an area in which the first light emitting electrode 171, the light emitting layer 172, and the second light emitting electrode 173 are sequentially stacked, and holes from the first light emitting electrode 171 and electrons from the second light emitting electrode 173 are combined with each other in the light emitting layer 172 to emit light.

In an embodiment, the light emitting layer 172 may be disposed on the first light emitting electrode 171 and the bank 190. The light emitting layer 172 may include an organic material to emit light in a predetermined color. For example, the light emitting layer 172 may include a hole transporting layer, an organic material layer, and an electron transporting layer.

In an embodiment, the second light emitting electrode 173 may be disposed on the light emitting layer 172. The second light emitting electrode 173 may be formed to cover the light emitting layer 172. The second light emitting electrode 173 may be a common layer shared by all of the emission areas EA1, EA2, and EA3. Although not shown, in some embodiments, a capping layer may be formed on the second light emitting electrode 173.

In an embodiment, in the top emission structure, the second light emitting electrode 173 may be formed of transparent conductive oxide (TCO) such as indium tin oxide (ITO) and indium zinc oxide (IZO) capable of transmitting light or a semi-transmissive conductive material such as magnesium (Mg), silver (Ag), or an alloy of magnesium (Mg) and silver (Ag). When the second light emitting electrode 173 is formed of a semi-transmissive conductive material, the light emission efficiency can be increased due to a micro-cavity effect.

In an embodiment, the encapsulation layer TFE may be disposed on the second light emitting electrode 173 and may include at least one inorganic film to prevent oxygen or moisture from permeating into the light emitting element layer. In addition, the encapsulation layer TFE may include at least one organic film to protect the light emitting element layer from foreign substances such as dust. For example, the encapsulation layer TFE may include a first encapsulation film TFE1, a second encapsulation film TFE2, and a third encapsulation film TFE3.

In an embodiment, the first encapsulation film TFE1 (e.g., a first inorganic encapsulation film) may be disposed on the second light emitting electrode 173 and may be an inorganic film of a single layer or multiple layers. The first encapsulation film TFE1 may be formed as a single layer or a multilayer in which one or more inorganic films of a silicon nitride layer, a silicon oxynitride layer, a silicon oxide layer, a titanium oxide layer and an aluminum oxide layer are alternately stacked.

In an embodiment, the second encapsulation film TFE2 (e.g., a first organic encapsulation film) may be disposed on the first encapsulation film TFE1 and may be an organic film of a single layer or multiple layers. The second encapsulation film TFE2 may include a polymer-based material. Polymer-based materials may include polyethylene terephthalate, polyethylene naphthalate, polycarbonate, polyimide, polyethylene sulfonate, polyoxymethylene, polyarylate, hexamethyldisiloxane, and acrylic resins (e.g., polymethyl methacrylate, polyacrylic acid, or the like), or any combination thereof.

In an embodiment, the third encapsulation film TFE3 (e.g., a second inorganic encapsulation film) may be disposed on the second encapsulation film TFE2 and may be an inorganic film of a single layer or multiple layers. The third encapsulation film TFE3 may include the same material as the first encapsulation film TFE1. For example, the third encapsulation film TFE3 may be formed as a single layer or a multilayer in which one or more inorganic films of a silicon nitride layer, a silicon oxynitride layer, a silicon oxide layer, a titanium oxide layer and an aluminum oxide layer are alternately stacked.

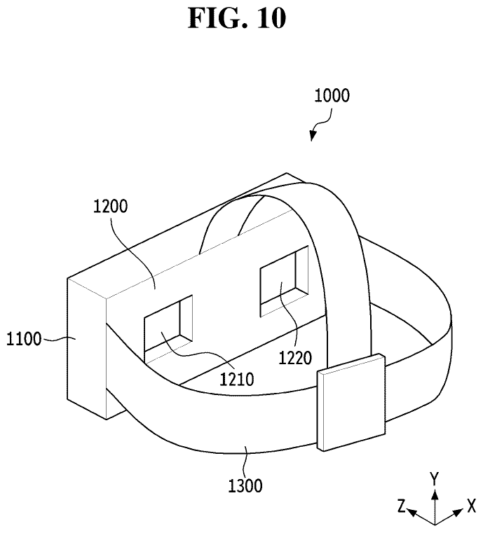

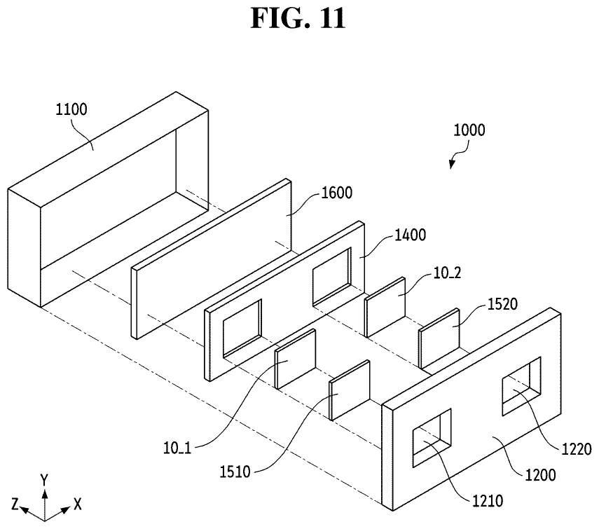

FIG. 10 is a perspective view illustrating a head mounted display, according to an embodiment. FIG. 11 is an exploded perspective view illustrating an example of the head mounted display of FIG. 9, according to an embodiment.

Referring to FIGS. 10 and 11, a head mounted display 1000, according to an embodiment, includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

In an embodiment, the first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 to 9, description of the first display device 10_1 and the second display device 10_2 will be omitted.

In an embodiment, the first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

In an embodiment, the middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

In an embodiment, the control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA and transmit the digital video data DATA to the first display device 10_1 and the second display device 10_2 through the connector.

In an embodiment, the control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

In an embodiment, the display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 10 and 11 illustrate that the first eyepiece 1210 and the second eyepiece 1220 are disposed separately, but the invention is not limited thereto. The first eyepiece 1210 and the second eyepiece 1220 may be combined into one.

In an embodiment, the first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

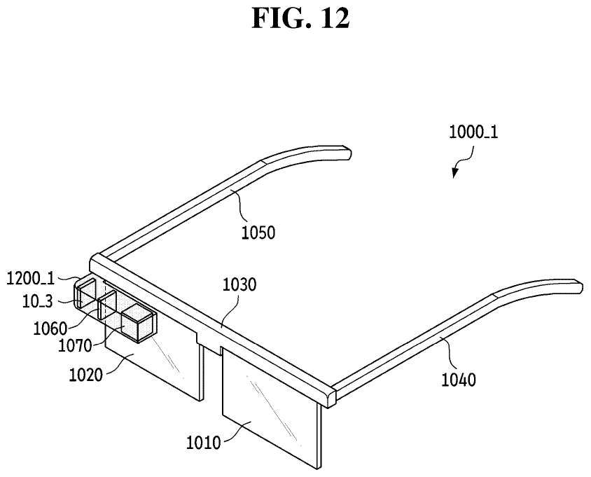

In an embodiment, the head mounted band 1300 serves to secure the display device housing 1100 to the user's head such that the first eyepiece 1210 and the second eyepiece 1220 of the housing cover 1200 remain located on the user's left and right eyes, respectively. When the display device housing 1200 is implemented to be lightweight and compact, the head mounted display 1000 may be provided with an eyeglass frame as shown in FIG. 12 instead of the head mounted band 1300.

FIG. 12 is a perspective view illustrating a head mounted display, according to an embodiment.

Referring to FIG. 12, a head mounted display 1000_1, according to an embodiment, may be an eyeglasses-type display device in which a display device housing 1200_1 is implemented in a lightweight and compact manner. The head mounted display 1000_1, according to an embodiment, may include a display device 10_3, a left eye lens 1010, a right eye lens 1020, a support frame 1030, temples 1040 and 1050, an optical member 1060, an optical path changing member 1070, and the display device housing 1200_1.

In an embodiment, the display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 12 illustrates an embodiment where the display device housing 1200_1 is disposed at the right end of the support frame 1030, but the invention is not limited thereto. For example, the display device housing 1200_1 may be disposed at the left end of the support frame 1030, and in this case, the image of the display device 10_3 may be provided to the user's left eye. In another embodiment, the display device housing 1200_1 may be disposed at both the left and right ends of the support frame 1030, and in this case, the user may view the image displayed on the display device 10_3 through both the left and right eyes.

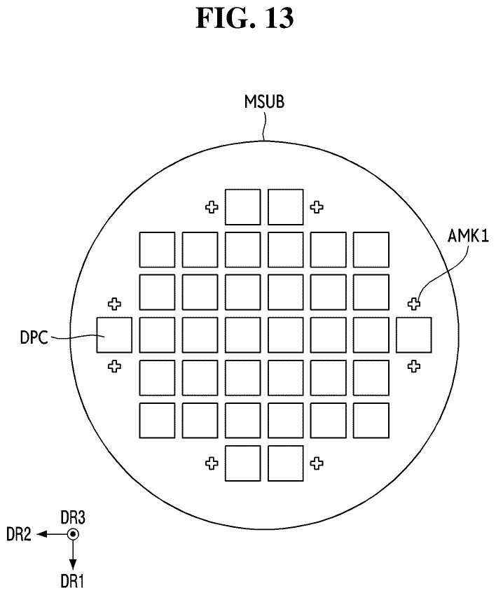

FIG. 13 is a plan view showing a mother semiconductor substrate including a display cell, according to an embodiment.

In an embodiment and referring to FIG. 13 in addition to FIGS. 7 to 9, a mother semiconductor substrate MSUB may be composed of a semiconductor wafer. The mother semiconductor substrate MSUB may contain a group IV material or a group III-V compound. In some embodiments, the mother semiconductor substrate MSUB may be composed of a single-crystal wafer. For example, the mother semiconductor substrate MSUB may be a silicon substrate, a germanium substrate, or a silicon-germanium substrate.

However, the mother semiconductor substrate MSUB is not limited to the single-crystal wafer, and in other embodiments may be any of various types of wafers such as an epi or epitaxial wafer, a polished wafer, an annealed wafer, and a silicon on insulator (SOI) wafer. An epitaxial wafer is a wafer in which a crystalline material is grown on a single-crystal silicon substrate.

In an embodiment, the mother semiconductor substrate MSUB may include a plurality of display cells DPC. Each of the plurality of display cells DPC may be a preprocessing component that constitutes a part of the display panel 100 described with reference to FIG. 1 and the like. For example, the mother semiconductor substrate MSUB may constitute the semiconductor substrate SSUB of the display panel 100, and the plurality of display cells DPC may constitute the semiconductor backplane SBP, the display element layer EML, and the encapsulation layer TFE of the display panel 100.

In an embodiment, the plurality of display cells DPC may be formed using semiconductor equipment or through a semiconductor process, but are not limited thereto. After forming the plurality of display cells DPC on the mother semiconductor substrate MSUB, the display panel 100 may be formed by performing cell cutting for each display cell DPC.

In an embodiment, although not shown in the drawing, each of the plurality of display cells DPC may include a plurality of pixels PX. Each of the plurality of pixels PX included in each of the plurality of display cells DPC may include a plurality of light emitting elements, and the light emitting stack IL (see FIGS. 7 and 8) or light emitting layer 172 (see FIG. 9) included in the light emitting element may be formed through a deposition process.

In an embodiment, the light emitting stack IL may be entirely disposed across the plurality of pixels PX, as shown in FIGS. 7 and 8, and the light emitting layers 172 may be individually disposed in the emission areas EA1, EA2, and EA3, as shown in FIG. 9. Regardless of the embodiments of FIGS. 7 to 9, a more precise deposition mask is required to form the light emitting stack IL or the light emitting layer 172 in the high-resolution display device 10. Hereinafter, a deposition mask for forming the high-resolution display device 10 will be described.

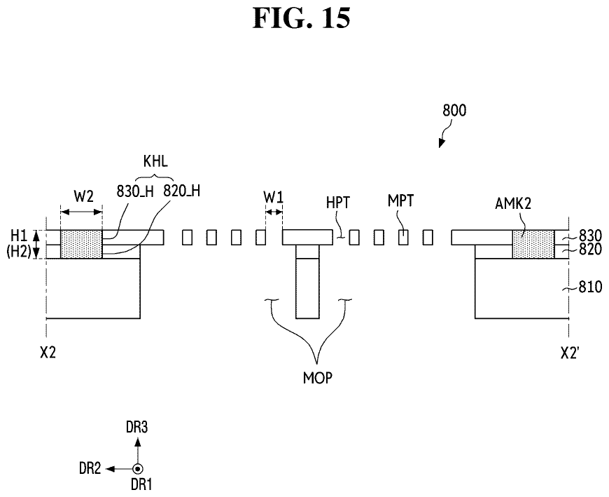

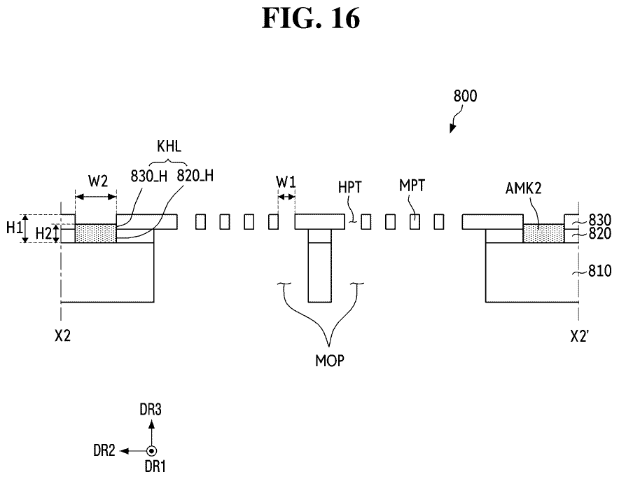

FIG. 14 is a plan view showing a deposition mask, according to an embodiment. FIG. 15 is a cross-sectional view showing an example of a cross section taken along line X2-X2′ of FIG. 14, according to an embodiment. FIG. 16 is a cross-sectional view showing another example of a cross section taken along line X2-X2′ of FIG. 14, according to an embodiment.

Referring to FIGS. 14 to 16 in addition to FIG. 13, the deposition mask 800, according to an embodiment, may be a deposition mask for use in manufacturing an ultra-high resolution display. For example, the deposition mask 800, according to an embodiment, may be a deposition mask for use in manufacturing a display included in the head mounted display or augmented reality content providing device described with reference to FIGS. 10 to 12.

In some embodiments, the deposition mask 800 may be used to perform a pixel deposition process on a silicon wafer rather than a large-area substrate used in a conventional display. For example, in the case of a display included in an extended reality device, since a screen is positioned directly in front of the user's eyes, it may have a small screen rather than a large one. In addition, since the display is positioned close to the user's eyes, ultra-high resolution may be required. For example, the required resolution of the display included in the extended reality device may be approximately 1000 PPI or more, and, desirably, an ultra-high resolution of 3000 PPI or more may be required. The deposition mask 800, according to an embodiment, may be a mask for use in manufacturing such an ultra-high resolution display. In some embodiments, the deposition mask 800 may be a fine silicon mask (FSM).

In an embodiment, the deposition mask 800 may include a mask substrate 810 and a plurality of mask cells MSC.

In an embodiment, the mask substrate 810 may be composed of a semiconductor wafer. The mask substrate 810 may contain a group IV material or a group III-V compound. In some embodiments, the mask substrate 810 may be composed of a single-crystal wafer. For example, the mask substrate 810 may be a silicon substrate, a germanium substrate, or a silicon-germanium substrate.

However, the mask substrate 810 is not limited to the single-crystal wafer, and, in an embodiment, may be any of various types of wafers such as an epi or epitaxial wafer, a polished wafer, an annealed wafer, and an SOI (silicon on insulator) wafer. An epitaxial wafer is a wafer in which a crystalline material is grown on a single-crystal silicon substrate.

In an embodiment, the mask substrate 810 may have a shape corresponding to a silicon wafer of an ultra-high resolution display. For example, the mask substrate 810 may have the same size or shape as the mother semiconductor substrate MSUB as a substrate of an ultra-high resolution display.

In an embodiment, the plurality of mask cells MSC may be arranged to correspond to the plurality of display cells DPC of the mother semiconductor substrate MSUB. For example, in a deposition process for manufacturing the display device 10 (see FIG. 1), the deposition mask 800 may be positioned on the mother semiconductor substrate MSUB. At this time, the plurality of mask cells MSC may overlap the plurality of display cells DPC of the mother semiconductor substrate MSUB, respectively.

In an embodiment, to align the plurality of mask cells MSC to overlap the plurality of display cells DPC, the mother semiconductor substrate MSUB may include a first alignment mark AMK1, and the deposition mask 800 may include a second alignment mark AMK2. The first alignment mark AMK1 and the second alignment mark AMK2 may each contain metal, but are not limited thereto.

In an embodiment, the plurality of mask cells MSC may be formed using semiconductor equipment or through a semiconductor process, but are not limited thereto. By forming the plurality of mask cells MSC on the mask substrate 810 composed of a semiconductor wafer using semiconductor equipment or through a semiconductor process, the deposition mask 800, according to the an embodiment, may be provided with an ultra-high resolution pattern. An ultra-high resolution display may be manufactured using this ultra-high resolution pattern.

In an embodiment, the deposition mask 800 may include the mask substrate 810, a first coating film 820, a second coating film 830, a mask opening MOP, a key hole KHL, and the second alignment mark AMK2.

A description of the mask substrate 810 will be omitted here as it has been already described above.

In an embodiment, the first coating film 820 may be disposed on the mask substrate 810. The first coating film 820 may be an inorganic film containing an inorganic material. For example, the first coating film 820 may contain silicon oxide (SiOₓ).

In an embodiment, the second coating film 830 may be disposed on the first coating film 820. The second coating film 830 may be an inorganic film containing an inorganic material. For example, the second coating film 830 may contain silicon nitride (SiNₓ).

In some embodiments, the second coating film 830 may contain low stress nitride (LSN). When the second coating film 830 contains the low stress nitride, the second coating film 830 may be formed by a low pressure chemical vapor deposition (LPCVD) process, but is not limited thereto. Since the second coating film 830 contains the low stress nitride, even if a plurality of mask patterns MPT and a plurality of hole patterns HPT to be described later are formed, the durability of the deposition mask 800 may be improved by a low stress.

In the drawing, the first coating film 820 and the second coating film 830 are illustrated as being disposed only on the top surface of the mask substrate 810, but are not limited thereto. In some embodiments, the first coating film 820 and the second coating film 830 may cover all of the top, bottom, and side surfaces of the mask substrate 810.

For example, in an embodiment, the first coating film 820 may include a first upper coating film disposed on the top surface of the mask substrate 810, a first lower coating film disposed on the bottom surface of the mask substrate 810, and a first side coating film disposed on the side surface of the mask substrate 810. The second coating film 830 may include a second upper coating film disposed on the top surface of the mask substrate 810, a second lower coating film disposed on the bottom surface of the mask substrate 810, and a second side coating film disposed on the side surface of the mask substrate 810. The second upper coating film may be disposed on the first upper coating film, the second lower coating film may be disposed on the first lower coating film, and the second side coating film may be disposed on the first side coating film.

In an embodiment, the deposition mask 800 may include the plurality of mask patterns MPT and the plurality of hole patterns HPT disposed in the second coating film 830. The plurality of mask patterns MPT and the plurality of hole patterns HPT may be disposed in the same layer as the second coating film 830. For example, the plurality of hole patterns HPT may be holes that penetrate at least a part of the second coating film 830 in the third direction DR3, and the plurality of mask patterns MPT may be other portions of the second coating film 830 that are not holes.

In an embodiment, the plurality of mask patterns MPT and the plurality of hole patterns HPT may be alternately arranged. For example, the plurality of mask patterns MPT and the plurality of hole patterns HPT may be alternately arranged in the first direction DR1 and/or the second direction DR2.

Although the plurality of mask patterns MPT are spaced apart from each other in the first direction DR1 or the second direction DR2 in cross-sectional view, they may be a single pattern connected to each other in a plan view. In the following description, the mask pattern MPT may refer to the whole of the plurality of patterns positioned on the mask substrate 810 as a single component, or may refer to each of the plurality of patterns. That is, the plurality of mask patterns MPT may be used interchangeably to refer to the whole group of the plurality of patterns as a single component or to refer to each of the plurality of patterns.

In an embodiment, the mask opening MOP may penetrate the mask substrate 810 and the first coating film 820. The mask opening MOP may overlap the mask pattern MPT and the hole pattern HPT in the third direction DR3. The mask opening MOP may be disposed below the mask pattern MPT and the hole pattern HPT in the third direction DR3.

In some embodiments, the mask opening MOP may not overlap the second alignment mark AMK2 and the key hole KHL, which will be described later, in the third direction DR3.

Although, in an embodiment, the inner surface of the mask opening MOP is depicted as a vertical plane in the drawing, it is not limited thereto. For example, the inner surface of the mask opening MOP may be sloped or curved due to the isotropy of a wet etching process.

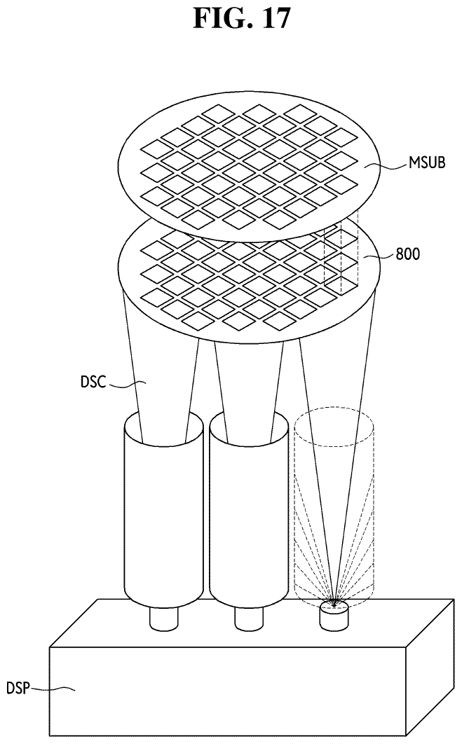

In an embodiment, the mask opening MOP may be connected to the hole pattern HPT. Accordingly, the mask opening MOP and the hole pattern HPT may provide a passage through which a deposition source DSC (see FIG. 17) can move. The mask substrate 810 and the mask pattern MPT may block the deposition source DSC (see FIG. 17) in an area other than the passage formed by the mask opening MOP and the hole pattern HPT being connected to each other.

In some embodiments, the mask opening MOP may be plural in number, corresponding to the mask cells MSC. For example, a plurality of mask openings MOP may be respectively disposed for the plurality of mask cells MSC. However, the invention is not limited thereto, and in other embodiments, the mask opening MOP may be formed as one across the plurality of mask cells MSC.

In an embodiment, the key hole KHL may be disposed on the mask substrate 810. The key hole KHL may penetrate the first coating film 820 and the second coating film 830. For example, the key hole KHL may include a second sub-key hole 820_H that penetrates the first coating film 820 and a first sub-key hole 830_H that penetrates the second coating film 830.

In an embodiment, the key hole KHL may overlap the mask pattern MPT, the hole pattern HPT, and the mask opening MOP in a horizontal direction (e.g., a direction perpendicular to the third direction DR3). The key hole KHL may not overlap the mask opening MOP in the third direction DR3.

In some embodiments, a width W2 of the key hole KHL may be larger than a width W1 of each of the plurality of hole patterns HPT. For example, the width W2 of the key hole KHL in the second direction DR2 may be larger than the width W1 of each of the plurality of hole patterns HPT in the second direction DR2.

In an embodiment, the second alignment mark AMK2 may be disposed in the key hole KHL. The second alignment mark AMK2 may be disposed on the mask substrate 810. The second alignment mark AMK2 may overlap at least one of the mask pattern MPT, the hole pattern HPT, or the mask opening MOP in the horizontal direction. The second alignment mark AMK2 may not overlap the mask opening MOP in the third direction DR3.

In some embodiments, a height H2 of the second alignment mark AMK2 may be substantially the same as or smaller than a height H1 of the key hole KHL in the third direction DR3. For example, as shown in FIG. 15, the height H2 of the second alignment mark AMK2 may be substantially the same as the height H1 of the key hole KHL in the third direction DR3. In another embodiment, as shown in FIG. 16, the height H2 of the second alignment mark AMK2 may be smaller than the height H1 of the key hole KHL in the third direction DR3. In an embodiment, the height H2 of the second alignment mark AMK2 may be approximately 50 nm or more.

In an embodiment, the top surface of the second alignment mark AMK2 may be exposed. For example, the first coating film 820 and the second coating film 830 may not be disposed on the top surface of the second alignment mark AMK2. The top surface of the second alignment mark AMK2 may not be in contact with the first coating film 820 and the second coating film 830.

In some embodiments, the width of the second alignment mark AMK2 may be the same as the width of the key hole KHL. For example, the width of the second alignment mark AMK2 in the second direction DR2 may be the same as the width of the key hole KHL. The outer side surface of the second alignment mark ANK2 may be in contact with the inner side surface of the key hole KHL.

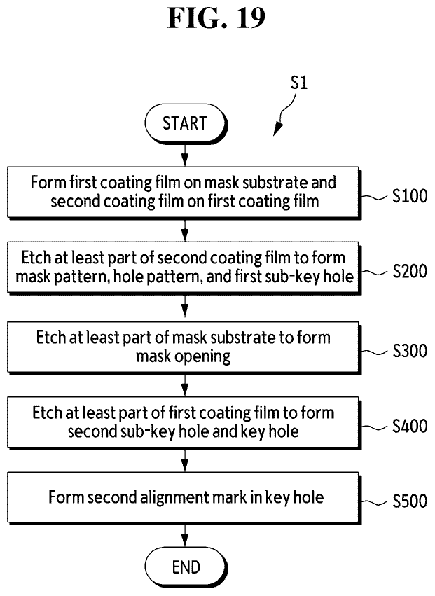

In an embodiment, in a deposition mask manufacturing method S1 (see FIG. 19) to be described later, as the key hole KHL is formed and then the second alignment mark AMK2 is formed in the key hole KHL, the top surface of the second alignment mark AMK2 may be exposed, and the outer side surface of the second alignment mark AMK2 may be in contact with the inner side surface of the key hole KHL.

In an embodiment, the second alignment mark AMK2 may contain a non-transmissive material. For example, the second alignment mark AMK2 may contain a material having a transmittance of 90% or less for visible light and near-infrared light with a wavelength of 370 nm or more. In some embodiments, the second alignment mark AMK2 may contain at least one of silver (Ag), aluminum (Al), molybdenum (Mo), tungsten (W), nickel (Ni), chromium (Cr), titanium (Ti), or an alloy made of a combination thereof. However, the invention is not limited thereto, the material contained in the second alignment mark AMK2 only needs to have a transmittance of 90% or less for visible light and near-infrared light with a wavelength of 370 nm or more, as described above.

In an embodiment, the deposition mask 800 may include the second alignment mark AMK2 containing a non-transmissive material, thereby improving the recognition rate of the alignment mark. Additionally, by forming the second alignment mark AMK2 in the key hole KHL, the quality reliability of the deposition mask 800 may be improved. This will be described in conjunction with the deposition mask manufacturing method S1 to be described later.

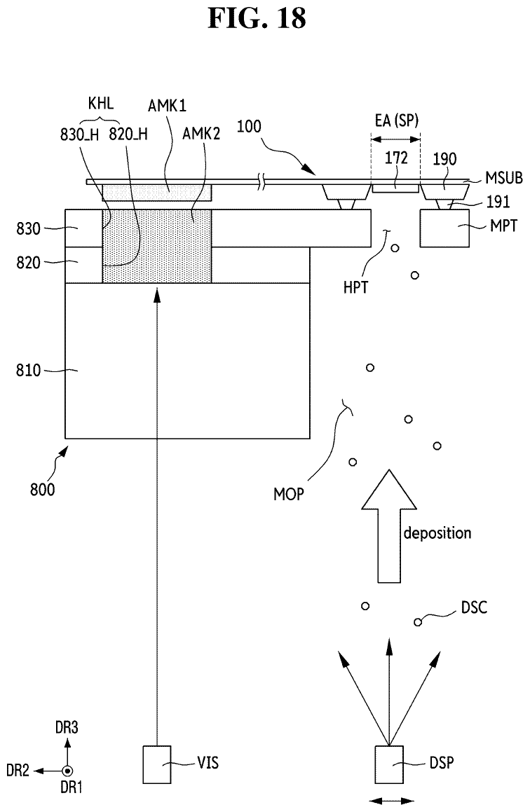

FIG. 17 is a perspective view showing a process of manufacturing a display device using a deposition mask, according to an embodiment. FIG. 18 is a cross-sectional view showing a process of manufacturing a display device using a deposition mask, according to an embodiment.

In an embodiment and referring to FIGS. 17 and 18, the deposition mask 800 may be used to form the light emitting layer 172 in the sub-pixel SP on the mother semiconductor substrate MSUB. The mother semiconductor substrate MSUB may be flipped and disposed at a location away from a deposition source supply DSP. For example, the mother semiconductor substrate MSUB may be disposed in an upward direction and the bank 190 of the sub-pixel SP may be disposed in a downward direction.

In an embodiment, when the sub-pixels SP each implement a different color, the material of the light emitting source included in the light emitting layer 172 of each of the sub-pixels SP may be different. That is, the deposition source DSC for forming the light emitting layer 172 of each of the sub-pixels SP may be different.

In an embodiment, when forming the light emitting layer 172 in one of the sub-pixels SP, the sub-pixel SP where the light emitting layer 172 is formed may be disposed to overlap the hole pattern HPT, and the sub-pixel SP where the light emitting layer 172 is not formed may be disposed to overlap the mask pattern MPT.

Accordingly, the deposition source DSC sprayed from the deposition source supply DSP may pass through the mask opening MOP and the hole pattern HPT only in the sub-pixel SP where the light emitting layer 172 is formed and be seated on the mother semiconductor substrate MSUB.

In an embodiment, the deposition mask 800 may be seated on the spacer 191 located on the bank 190. For example, the top surface of the mask pattern MPT may be seated on the spacer 191. The top surface of the mask pattern MPT may be in direct contact with the spacer 191.

In an embodiment, in order to align the positions of the hole pattern HPT and the sub-pixel SP where and the light emitting layer 172 is to be formed, the second alignment mark AMK2 and the first alignment mark AMK1 on the mother semiconductor substrate MSUB may be disposed to overlap each other in the third direction DR3.

In an embodiment, the alignment of the first alignment mark AMK1 and the second alignment mark AMK2 may be inspected by a vision device VIS. The vision device VIS may irradiate the deposition mask 800 with visible light and near-infrared light having a wavelength of about 370 nm or more. Visible light and near-infrared light having a wavelength of about 370 nm or more may pass through the mask substrate 810, but may not pass through the second alignment mark AMK2. Accordingly, the second alignment mark AMK2 may be recognized. The first alignment mark AMK1 may be recognized in the same manner.

Hereinafter, a method for manufacturing the deposition mask 800 will be described, according to an embodiment.

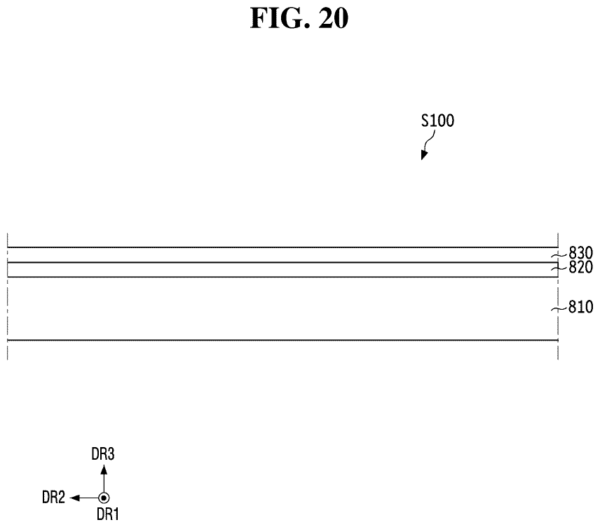

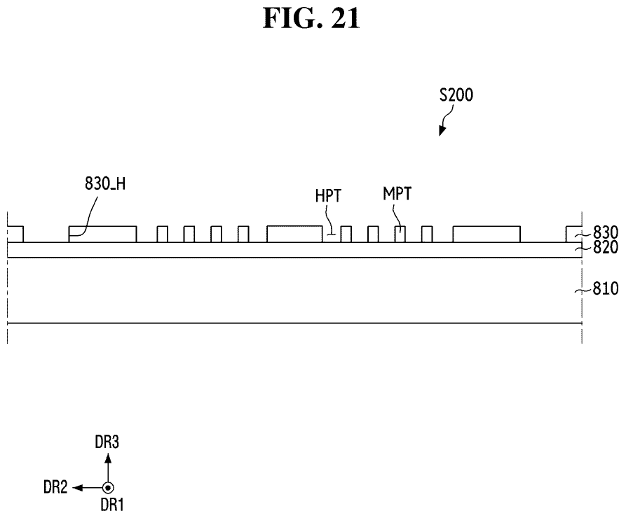

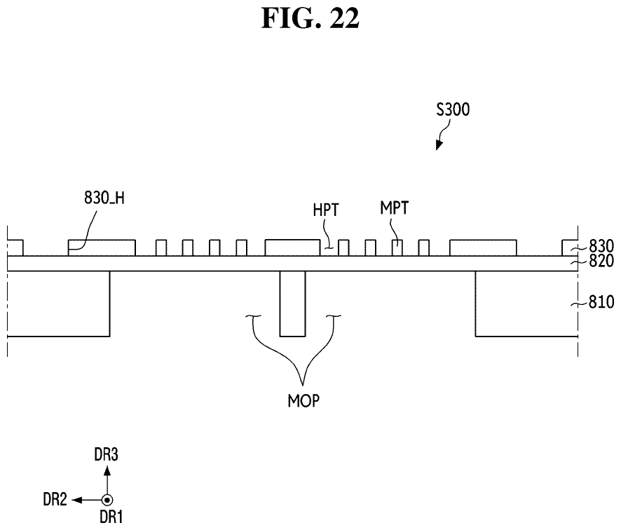

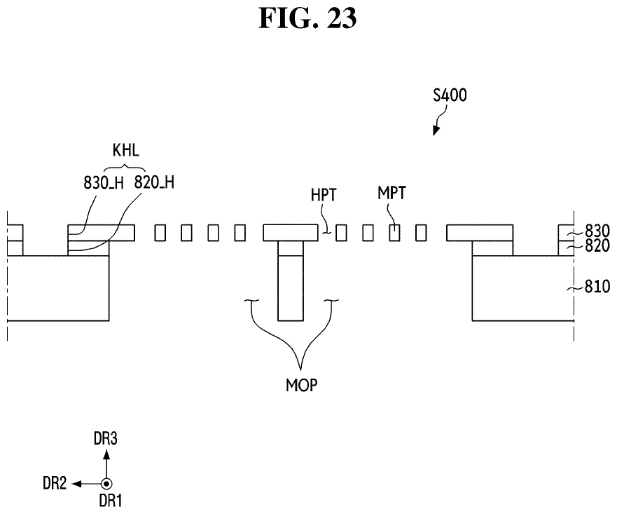

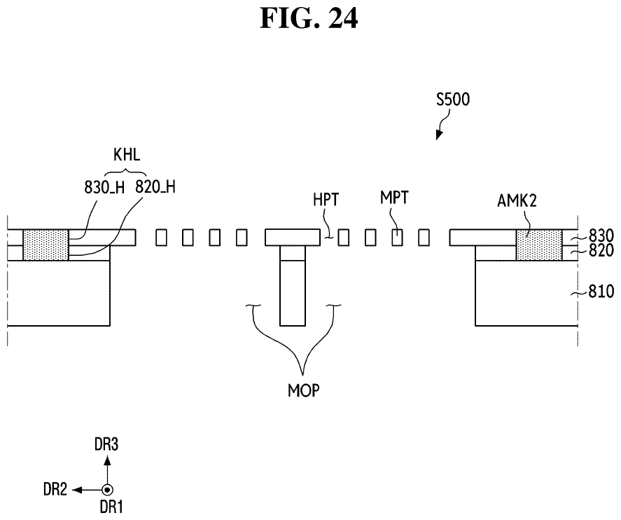

FIG. 19 is a flowchart showing a method for manufacturing a deposition mask, according to an embodiment. FIG. 20 is a cross-sectional view showing step S100 of FIG. 19, according to an embodiment. FIG. 21 is a cross-sectional view showing step S200 of FIG. 19, according to an embodiment. FIG. 22 is a cross-sectional view showing step S300 of FIG. 19, according to an embodiment. FIG. 23 is a cross-sectional view showing step S400 of FIG. 19, according to an embodiment. FIG. 24 is a cross-sectional view showing step S500 of FIG. 19, according to an embodiment.

In an embodiment and referring to FIGS. 19 to 24, the deposition mask manufacturing method S1 may include forming the first coating film and the second coating film on the mask substrate (step S100), forming the mask pattern, the hole pattern, and the first sub-key hole (step S200), forming the mask opening (step S300), forming the second sub-key hole and the key hole (step S400), and forming the second alignment mark in the key hole (step S500).

Firstly, in an embodiment and as shown in FIG. 20, in step S100 of forming the first coating film and the second coating film on the mask substrate, the mask substrate 810 may be provided. The mask substrate 810 may be composed of a semiconductor wafer, as described above. A description of the mask substrate 810 will be omitted here as it has been already described above.

Next, in an embodiment, the first coating film 820 may be deposited on the mask substrate 810. The first coating film 820 may be an inorganic film containing an inorganic material as described above. For example, the first coating film 820 may contain silicon oxide (SiOₓ).

In some embodiments, the first coating film 820 may be formed by thermal evaporation. In this case, the first coating film 820 may be formed under a temperature condition of approximately 900° C. to about 1100° C., but is not limited thereto.

Then, in an embodiment, the second coating film 830 may be deposited on the first coating film 820, where the second coating film 830 may be an inorganic film containing an inorganic material as described above. For example, the second coating film 830 may contain silicon nitride (SiNₓ). In some embodiments, the second coating film 830 may contain low stress nitride (LSN).

In some embodiments, the second coating film 830 may be formed by a low pressure chemical vapor deposition (LPCVD) process. In this case, the second coating film 830 may be formed under a temperature condition of approximately 700° C. to about 900° C., but is not limited thereto.

Secondly, in an embodiment and as shown in FIG. 21, in step S200 of forming the mask pattern, the hole pattern, and the first sub-key hole, the second coating film 830 may be patterned to form the mask pattern MPT, the hole pattern HPT, and the first sub-key hole 830_H.

The etching process of the second coating film 830 may be performed using dry etching. For example, through a photolithography process, a photoresist may be left only in a portion where the mask pattern MPT is to be formed, and using this as a mask, plasma may be applied to a portion where the hole pattern HPT and the first sub-key hole 830_H are to be formed to pattern the second coating film 830.

In the deposition mask manufacturing method S1, according to an embodiment, since the mask pattern MPT, the hole pattern HPT, and the first sub-key hole 830_H are simultaneously formed through a patterning process, it is possible to minimize an error in the relative position between the hole pattern HPT and the key hole KHL. Thus, an error in the relative position between the hole pattern HPT and the second alignment mark AMK2 may be minimized compared to the case of forming the second alignment mark AMK2 separately from the hole pattern HPT without the key hole KHL.

Thirdly, in an embodiment and as shown in FIG. 22, in step S300 of forming the mask opening, at least a part of the mask substrate 810 may be etched to form the mask opening MOP.

The etching process of the mask substrate 810 may be performed using wet etching. Therefore, although the inner surface of the mask opening MOP is depicted as being a vertical plane in the drawing, the shape of the opening mask MOP is not limited thereto. For example, the inner surface of the mask opening MOP may be sloped or curved due to the isotropy of the wet etching. In some embodiments, the wet etching of the mask opening MOP may be performed using a tetramethylammonium hydroxide (TMAH) solution or a potassium hydroxide (KOH) solution as an etchant.

Fourthly, in an embodiment and as shown in FIG. 23, in step S400 of forming the second sub-key hole and the key hole, at least a part of the first coating film 820 may be etched to form the second sub-key hole 820_H and the key hole KHL. At the same time, the first coating film 820 located below the hole pattern HPT and the mask pattern MPT may also be removed, allowing the mask opening MOP to communicate with the hole pattern HPT to form a through hole.

In an embodiment, the etching process of the first coating film 820 may be performed using wet etching. Accordingly, in the drawing, the shape of the inner side surface of the first coating film 820 is shown as a vertical surface, but is not limited thereto. For example, the inner side surface of the first coating film 820 may have an inclined or curved surface shape due to the isotropy of wet etching. In some embodiments, the wet etching of the first coating film 820 may be performed using a buffered oxide etchant (BOE) solution as an etchant.

In an embodiment, since etching is performed in all directions due to the characteristics of wet etching, a portion of the first coating film 820 disposed below the first sub-key hole 830_H may be etched in a top-to-bottom direction, and a portion of the first coating film 820 disposed above the mask opening MOP may be etched in a bottom-to-top direction.

In an embodiment, a portion of the first coating film 820 disposed below the first sub-key hole 830_H may be completely etched to form the second sub-key hole 820_H. The first sub-key hole 830_H and the second sub-key hole 820_H may form a single key hole KHL. A portion of the first coating film 820 disposed above the mask opening MOP may be completely etched, allowing the mask opening MOP and the hole pattern HPT to communicate with each other and form a through hole.

In the deposition mask manufacturing method S1, according to an embodiment, since the second alignment mark AMK2 is disposed in the key hole KHL, the width of the second alignment mark AMK2 may be controlled to the width of the key hole KHL, so that alignment accuracy using the second alignment mark AMK2 may be improved.

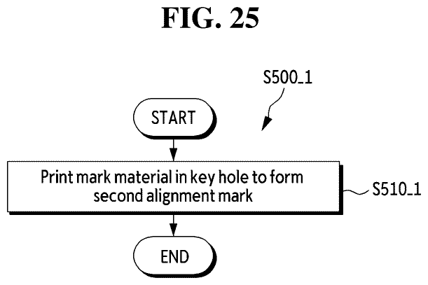

Fifthly, in an embodiment and as shown in FIG. 24, in step S500 of forming the second alignment mark in the key hole, a material for forming the second alignment mark AMK2 may be disposed in the key hole KHL. Various methods for forming the second alignment mark AMK2 will be described later with reference to FIGS. 25 to 35.

In the deposition mask manufacturing method S1, according to an embodiment, since the second alignment mark AMK2 is formed after the first coating film 820 and the second coating film 830 are formed, damage to the second alignment mark AMK2 may be minimized. For example, the first coating film 820 and the second coating film 830 may be formed under a high temperature condition of about 600° C. or more as described above, and if the second alignment mark AMK2 is formed first and then the first coating film 820 or the second coating film 830 is formed, the second alignment mark AMK2 may be damaged due to the high temperature.

In contrast, in the deposition mask manufacturing method S1, according to an embodiment, since the second alignment mark AMK2 is formed after the first coating film 820 and the second coating film 830 are formed, damage to the second alignment mark AMK2 may be minimized. Additionally, the generation of particles due to damage to the second alignment mark AMK2 may be minimized, thereby improving the quality reliability of the deposition mask.

In the deposition mask manufacturing method S1, according to an embodiment, since the second alignment mark AMK2 is formed after the mask pattern MPT, the hole pattern HPT, the key hole KHL, and the mask opening MOP are formed, damage to the second alignment mark AMK2 may be minimized. For example, when the second coating film 830 is dry etched to form the mask pattern MPT and the hole pattern HPT, when the mask substrate 810 is wet etched to form the mask opening MOP, or when the first coating film 820 is wet etched to form the key hole KHL, if the second alignment mark AMK2 is formed first and then the etching or patterning process is performed, the second alignment mark AMK2 may be partially etched, resulting in damage to the second alignment mark AMK2.

In contrast, in the deposition mask manufacturing method S1, according to an embodiment, since the second alignment mark AMK2 is formed after the mask pattern MPT, the hole pattern HPT, the key hole KHL, and the mask opening MOP are formed, damage to the second alignment mark AMK2 may be minimized. Additionally, the generation of particles due to damage to the second alignment mark AMK2 may be minimized, thereby improving the quality reliability of the deposition mask.

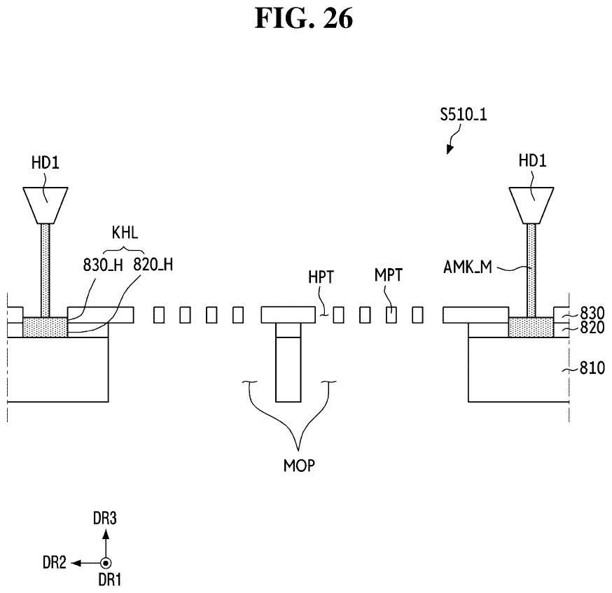

FIG. 25 is a flowchart illustrating a step of forming a second alignment mark, according to an embodiment. FIG. 26 is a cross-sectional view showing step S510_1 of FIG. 25, according to an embodiment.

Referring to FIGS. 25 and 26, step S500_1 of forming the second alignment mark, according to an embodiment, may include printing a mark material in the key hole to form the second alignment mark (step S510_1).

For example, in an embodiment and as shown in FIG. 26, in step S510_1 of printing a mark material in the key hole to form the second alignment mark, a first head HD1 may print a mark material AMK_M in the key hole KHL. The first head HD1 may be a 3D printer. The first head HD1 may have an error margin of 10 nm or less.

In some embodiments, in order to prevent the mark material AMK_M from overflowing, the mark material AMK_M may be filled in the key hole KHL only up to a height lower than the height of the key hole KHL in the third direction DR3. Accordingly, as described with reference to FIG. 16, the height H2 (see FIG. 16) of the second alignment mark AMK2 may be smaller than the height H1 (see FIG. 16) of the key hole KHL.

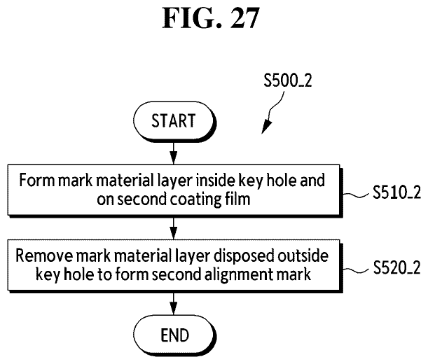

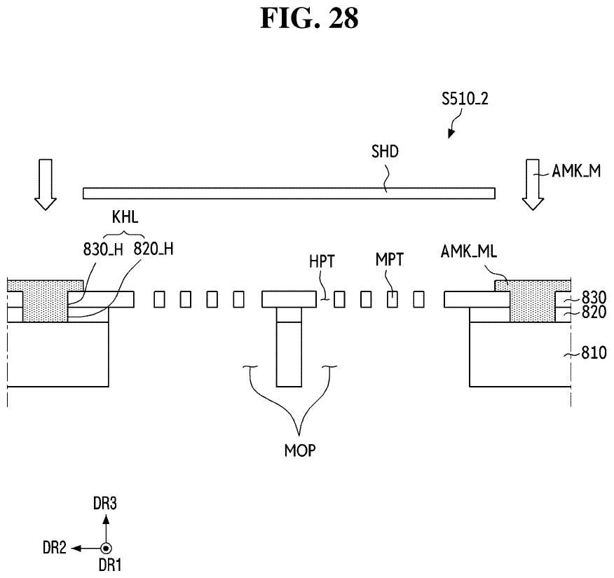

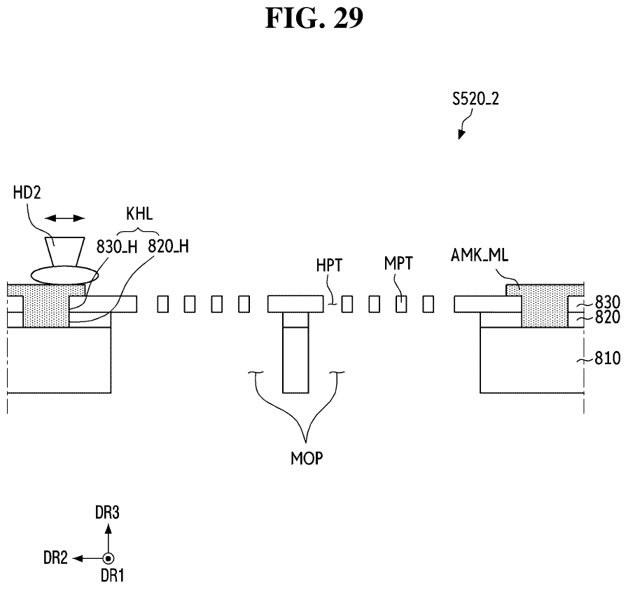

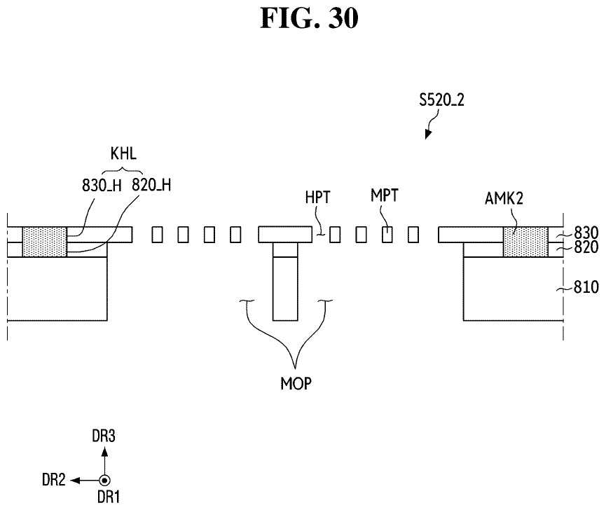

FIG. 27 is a flowchart illustrating a step of forming a second alignment mark, according to another embodiment. FIG. 28 is a cross-sectional view showing step S510_2 of FIG. 27, according to an embodiment. FIGS. 29 and 30 are cross-sectional views showing step S520_2 of FIG. 27, according to other embodiments.

Referring to FIGS. 27 to 30, step S500_2 of forming the second alignment mark, according to another embodiment, may include forming a mark material layer inside the key hole and on the second coating film (step S510_2), and removing the mark material layer disposed outside the key hole to form the second alignment mark (step S520_2).

First, in an embodiment and as shown in FIG. 28, in step S510_2 of forming a mark material layer inside the key hole and on the second coating film, a protective film SHD may be disposed above a region overlapping the hole pattern HPT and the mask pattern MPT. In the drawing, the protective film SHD is shown as being spaced apart from the top surface of the second coating film 830, but it is not limited thereto, the protective film SHD may be in direct contact with the top surface of the second coating film 830.

In an embodiment, the protective film SHD may be a structure that can physically block the mark material AMK_M. For example, the protective film SHD may be a plate-shaped structure. However, the invention is not limited thereto, and in other embodiments, the protective film SHD may be a thin film such as a photoresist.

In an embodiment, the mark material AMK_M may be disposed inside the key hole KHL and on the second coating film 830 in a portion that does not overlap the protective film SHD. For example, the mark material AMK_M may be deposited as a film through a deposition process. Accordingly, a mark material layer AMK_ML may be formed inside the key hole KHL and on the second coating film 830 in a portion that does not overlap the protective film SHD.

Next, in an embodiment and as shown in FIG. 29, in step S520_2 of removing the mark material layer disposed outside the key hole to form the second alignment mark, a second head HD2 may remove the mark material layer AMK_ML disposed outside the key hole KHL.

In an embodiment, the removal of the mark material layer AMK_ML may be performed by a chemical mechanical polishing process, where the second head HD2 may be a polishing device. For example, the second head HD2 may include a polishing pad.

In an embodiment, the second head HD2 may remove the mark material layer AMK_ML located above the key hole KHL and on the second coating film 830. Accordingly, as shown in FIG. 30, the second alignment mark AMK2 may be formed inside the key hole KHL.

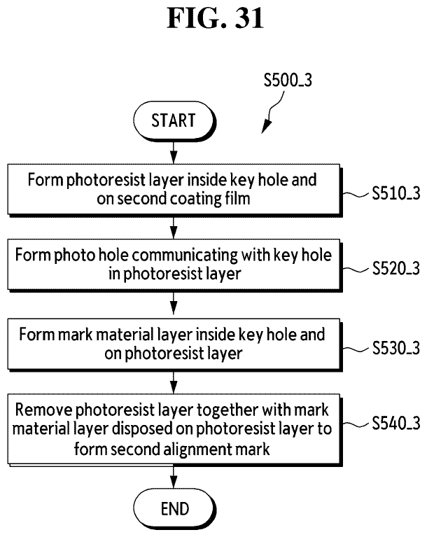

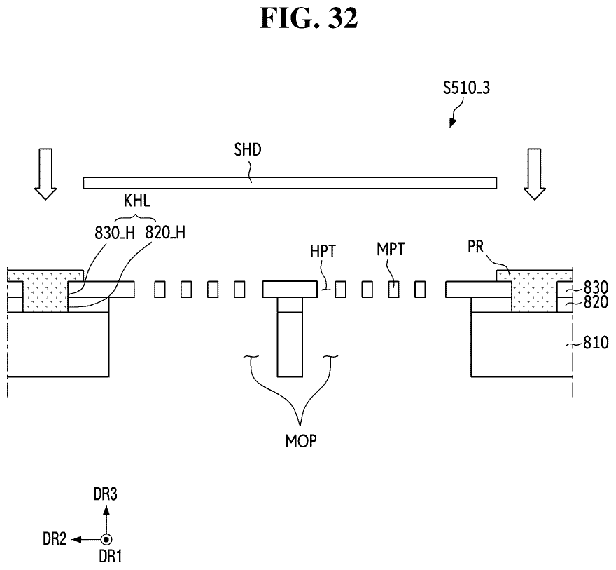

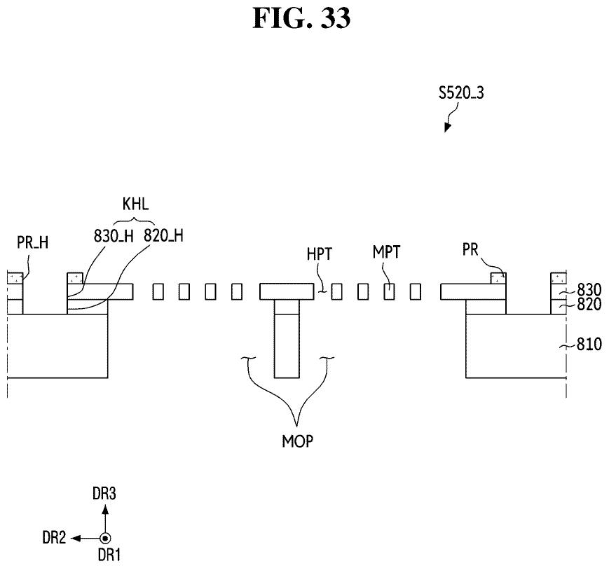

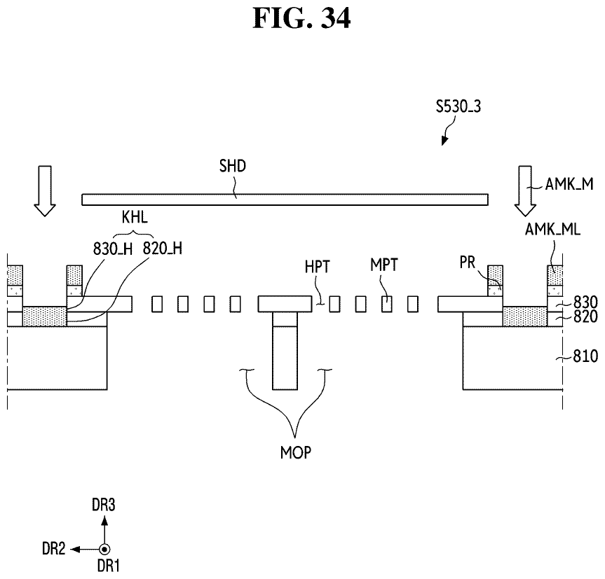

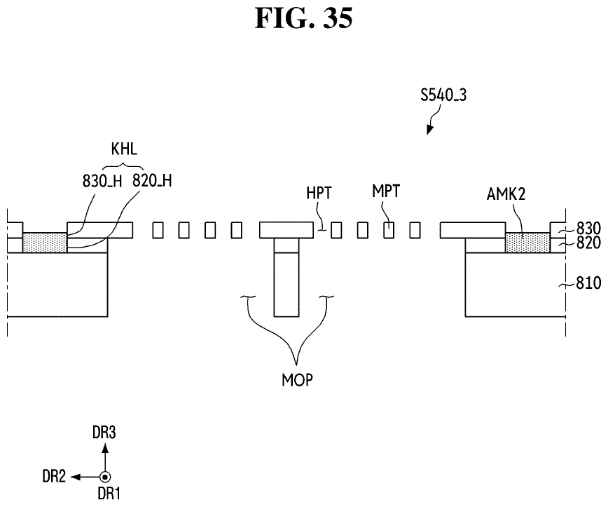

FIG. 31 is a flowchart illustrating a step of forming a second alignment mark, according to still another embodiment. FIG. 32 is a cross-sectional view showing step S510_3 of FIG. 31, according to an embodiment. FIG. 33 is a cross-sectional view showing step S520_3 of FIG. 31, according to an embodiment. FIG. 34 is a cross-sectional view showing step S530_3 of FIG. 31, according to an embodiment. FIG. 35 is a cross-sectional view showing step S540_3 of FIG. 31, according to an embodiment.

Referring to FIGS. 31 to 35, step S500_3 of forming the second alignment mark, according to another embodiment, may include forming a photoresist layer inside the key hole and on the second coating film (step S510_3), forming a photo hole communicating with the key hole in the photoresist layer (step S520_3), forming a mark material layer inside the key hole and on the photoresist layer (step S530_3), and removing the photoresist layer together with the mark material layer disposed on the photoresist layer to form the second alignment mark (step S540_3).

First, in an embodiment and as shown in FIG. 32, in step S510_3 of forming a photoresist layer inside the key hole and on the second coating film, the protective film SHD may be disposed above a region overlapping the hole pattern HPT and the mask pattern MPT. Since the protective film SHD, according to an embodiment, is substantially the same as the protective film SHD described with reference to FIG. 28, an additional description will be omitted.

In an embodiment, a photoresist layer PR may be disposed inside the key hole KHL and on the second coating film 830 in a portion that does not overlap the protective film SHD. For example, the photoresist layer PR may be formed through a coating process.

Next, in an embodiment and as shown in FIG. 33, in step S520_3 of forming a photo hole communicating with the key hole in the photoresist layer, the photoresist layer PR may be removed from a region overlapping the key hole KHL. For example, the photoresist layer PR may be removed through an exposure and development process. The photoresist layer PR may be removed from a portion overlapping the key hole KHL to form a photo hole PR_H. The photo hole PR_H may communicate with the key hole KHL.

Next, in an embodiment and as shown in FIG. 34, in step S530_3 of forming a mark material layer inside the key hole and on the photoresist layer, the protective film SHD may be disposed above a region overlapping the hole pattern HPT and the mask pattern MPT.

In an embodiment, the mark material AMK_M may be disposed inside the key hole KHL and on the photoresist layer PR in a portion that does not overlap the protective film SHD. For example, the mark material AMK_M may be deposited as a film through a deposition process. Accordingly, the mark material layer AMK_ML may be formed inside the key hole KHL and on the photoresist layer PR in a portion that does not overlap the protective film SHD.

In some embodiments, in order to prevent the mark material layer AMK_ML from being formed higher than the key hole KHL, the mark material AMK_M may be filled in the key hole KHL only up to a height lower than the height of the key hole KHL in the third direction DR3. Accordingly, as described with reference to FIG. 16, the height H2 (see FIG. 16) of the second alignment mark AMK2 may be smaller than the height H1 (see FIG. 16) of the key hole KHL.

Next, in an embodiment and as shown in FIG. 35, in step S540_3 of removing the photoresist layer together with the mark material layer disposed on the photoresist layer to form the second alignment mark, the photoresist layer PR may be removed. The photoresist layer PR may be removed by a stripping process. When the photoresist layer PR is removed, the mark material layer AMK_ML disposed on the photoresist layer PR may also be removed. Accordingly, the second alignment mark AMK2 may remain only inside the key hole KHL.

In concluding the detailed description, those skilled in the art will appreciate that many variations and modifications can be made to the invention without substantially departing from the principles and scope of the invention. Therefore, the disclosed embodiments of the invention are used in a generic and descriptive sense only and not for purposes of limitation.

What is claimed is:

1. A method for manufacturing a deposition mask, comprising:
forming a first coating film on a mask substrate, and a second coating film on the first coating film;
etching at least a part of the second coating film to form a mask pattern, a hole pattern, and a first sub-key hole;
etching at least a part of the mask substrate to form a mask opening;
etching at least a part of the first coating film to form a second sub-key hole and a key hole; and
forming a second alignment mark inside the key hole.

2. The method of claim 1, wherein the mask substrate contains silicon,
the first coating film contains silicon oxide, and
the second coating film contains silicon nitride.

3. The method of claim 2, wherein the second coating film contains low stress nitride.

4. The method of claim 3, wherein the first coating film is formed by thermal evaporation, and
the second coating film is formed by a low pressure chemical vapor deposition (LPCVD) process.

5. The method of claim 1, wherein the hole pattern and the first sub-key hole are formed by the same process.

6. The method of claim 1, wherein the forming of the second alignment mark is performed after the forming of the first coating film and the second coating film.

7. The method of claim 1, wherein the forming of the second alignment mark is performed after the forming of the mask opening and the forming of the second sub-key hole.

8. The method of claim 1, wherein the forming of the second alignment mark comprises printing a mark material inside of the key hole.

9. The method of claim 1, wherein the forming of the second alignment mark comprises removing a mark material layer disposed on the second coating film.

10. The method of claim 9, wherein the removing of the mark material layer comprises performing a chemical mechanical polishing (CMP) process.

11. The method of claim 1, wherein the forming of the second alignment mark comprises removing a mark material layer disposed on the photoresist layer together with removal of a photoresist layer.

12. The method of claim 11, wherein the removal of the photoresist layer is performed by a stripping process.

13. A deposition mask comprising:
a mask substrate composed of a semiconductor wafer;
a first coating film disposed on the mask substrate;
a second coating film disposed on the first coating film, and comprising a hole pattern and a mask pattern alternately disposed;
a key hole penetrating the first coating film and the second coating film; and
an alignment mark disposed inside the key hole.

14. The deposition mask of claim 13, wherein the key hole comprises a first sub-key hole penetrating the first coating film and a second sub-key hole penetrating the second coating film.

15. The deposition mask of claim 13, further comprising a mask opening penetrating the mask substrate and the first coating film,
wherein the mask opening overlaps the mask pattern and the hole pattern.

16. The deposition mask of claim 15, wherein at least one of
the mask opening does not overlap the key hole, and
the key hole and the mask are communicated with each other to form a through hole.

17. The deposition mask of claim 13, wherein a top surface of the alignment mark is exposed.

18. The deposition mask of claim 13, wherein the top surface of the alignment mark is not in contact with the first coating film and the second coating film.

19. The deposition mask of claim 13, wherein a side surface of the alignment mark is in direct contact with a side surface of the key hole.

20. An electronic device, comprising:
a display device, wherein the display device is constructed using a deposition mask, wherein the deposition mask includes,
a mask substrate composed of a semiconductor wafer;
a first coating film disposed on the mask substrate;
a second coating film disposed on the first coating film, and comprising a hole pattern and a mask pattern alternately disposed;
a key hole penetrating the first coating film and the second coating film; and
an alignment mark disposed inside the key hole.
